(19) United States
(12) Patent Application Publication
(10) Pub. No.: US 2021/0202551 A1
(43) Pub. Date: Jul. 1, 2021

(54) IMAGING DEVICE AND METHOD FOR DRIVING IMAGING DEVICE

(71) Applicant: Panasonic Intellectual Property Management Co., Ltd., Osaka (JP)

(72) Inventors: KATSUYA NOZAWA, Osaka (JP); TAKEYOSHI TOKUHARA, Osaka (JP); NOZOMU MATSUKAWA, Nara (JP); SANSHIRO SHISHIDO, Osaka (JP)

(21) Appl. No.: 17/204,851

(22) Filed: Mar. 17, 2021

Related U.S. Application Data
(63) Continuation of application No. PCT/JP2020/002166, filed on Jan. 22, 2020.

(30) Foreign Application Priority Data
Feb. 20, 2019 (JP) 2019-028538

(51) Int. Cl. H01L 27/146

(52) U.S. Cl. CPC H01L 27/14612; H01L 27/14621; H01L 27/1461; H01L 27/14643

(57) ABSTRACT

An imaging device includes a pixel electrode, a counter electrode, a first quantum dot that includes a first core which generates first signal charge and a first shell, a second quantum dot that includes a second core which generates second signal charge and a second shell. In a case where the potential difference between the pixel electrode and the counter electrode is a first potential difference, the first signal charge does not pass through the first shell and is held in the first core and the second signal charge passes through the second shell and is collected by the pixel electrode. In a case where the potential difference between the pixel electrode and the counter electrode is a second potential difference which is larger than the first potential difference, the first signal charge passes through the first shell and is collected by the pixel electrode.

### BACKGROUND

### 1. Technical Field

The present disclosure relates to an imaging device and a method for driving the imaging device.

### 2. Description of the Related Art

An imaging device in which photoelectric conversion elements whose spectral sensitivity characteristics are different from one another are stacked on one another is known.

U.S. Pat. No. 5,965,875 discloses an imaging device including photoelectric conversion regions in a single-crystal semiconductor. The thickness of each of the photoelectric conversion regions is adjusted such that the photoelectric conversion region absorbs blue light, green light, and red light from a front surface side. Signal charge generated as a result of photoelectric conversion is read from an electrode connected to each of the photoelectric conversion regions.

Japanese Patent No. 560470B discloses a configuration in which an impurity region that has an opposite conduction system to a photodiode and that separates the photodiode in a vertical direction halfway in a thickness direction of the photodiode is provided, In Japanese Patent No. 560470B, the barrier height of the impurity region is controlled using pulse voltage applied to an accumulation gate in order to control transfer of signal charge between parts of the photodiode separated in an incident direction. As a result, signal charge can be read without providing an electrode for each of photodiodes stacked on one another.

### SUMMARY

In one general aspect, the techniques disclosed here feature an imaging device including a pixel electrode, a counter electrode that faces the pixel electrode, a first quantum dot that includes a first core and a first shell and that is located between the pixel electrode and the counter electrode, the first core generating first signal charge, the first shell covering the first core and forming a first heterojunction barrier against the first signal charge, a second quantum dot that includes a second core and a second shell and that is located between the pixel electrode and the counter electrode, the second core generating second signal charge, the second shell covering the second core and forming a second heterojunction barrier against the second signal charge, and a charge accumulator that is electrically connected to the pixel electrode and that accumulates the first signal charge and the second signal charge. The first quantum dot and the second quantum dot are type-II quantum dots. In a case where a potential difference between the pixel electrode and the counter electrode is a first potential difference, the first signal charge does not pass through the first heterojunction barrier and is held in the first core and the second signal charge passes through the second heterojunction barrier and is collected by the pixel electrode. In a case where the potential difference between the pixel electrode and the counter electrode is a second potential difference which is larger than the first potential difference, the first signal charge passes through the first heterojunction barrier and is collected by the pixel electrode.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a circuit diagram illustrating an exemplary circuit configuration of an imaging device according to a first embodiment;

FIG. 2 is a schematic cross-sectional view of the cross-sectional structure of one of pixels of the imaging device according to the first embodiment;

FIG. 3 is a schematic diagram illustrating the structure and energy levels of a hole confining type-II quantum dot;

FIG. 4 is a schematic diagram illustrating the structure and energy levels of an electron confining type-II quantum dot;

FIG. 5 is a diagram illustrating the distribution of quantum dots included in quantum dot groups fabricated by a general manufacturing method;

FIG. 6 is a diagram illustrating absorption spectra of quantum dot groups whose peaks of resonant frequencies are different from each other;

FIG. 7 is a schematic diagram illustrating the structure of a photoelectric conversion layer in the imaging device and charge generated during exposure according to the first embodiment;

FIG. 8 is a diagram illustrating a relationship between the amount of signal charge generated by the photoelectric conversion layer and bias voltage according to the first embodiment;

FIG. 9 is a timing chart illustrating an example of a method for driving the imaging device according to the first embodiment;

FIG. 10 is a schematic diagram illustrating movement of charge during the exposure in the imaging device according to the first embodiment;

FIG. 11 is a schematic diagram illustrating a state of charge immediately before transfer in the imaging device according to the first embodiment;

FIG. 12 is a schematic diagram illustrating movement of charge during the transfer in the imaging device according to the first embodiment;

FIG. 13 is a timing chart illustrating another example of the method for driving the imaging device according to the first embodiment;

FIG. 14 is a schematic diagram illustrating the structure of a photoelectric conversion layer in an imaging device and charge generated during exposure according to a second embodiment;

FIG. 15 is a schematic diagram illustrating movement of charge during exposure in the imaging device according to the second embodiment;

FIG. 16 is a schematic diagram illustrating a state of charge immediately before transfer in the imaging device according to the second embodiment;

FIG. 17 is a schematic diagram illustrating movement of charge during the transfer in the imaging device according to the second embodiment;

FIG. 18 is a schematic diagram illustrating the structure of a photoelectric conversion layer in an imaging device and charge generated during exposure according to a third embodiment;

FIG. 19 is a timing chart illustrating an example of a method for driving the imaging device according to the third embodiment;

FIG. 20 is a schematic diagram illustrating movement of charge during exposure in the imaging device according to the third embodiment;

FIG. 21 is a schematic diagram illustrating a state of charge immediately before first transfer in the imaging device according to the third embodiment;

FIG. 22 is a schematic diagram illustrating movement of charge during the first transfer in the imaging device according to the third embodiment;

FIG. 23 is a schematic diagram illustrating a state of charge immediately before second transfer in the imaging device according to the third embodiment;

FIG. 24 is a schematic diagram illustrating movement of charge during the second transfer in the imaging device according to the third embodiment;

FIG. 25 is a timing chart illustrating another example of the method for driving the imaging device according to the third embodiment;

FIG. 26 is a schematic cross-sectional view of the cross-sectional structure of one of pixels of an imaging device according to a fourth embodiment;

FIG. 27 is a schematic cross-sectional view of the cross-sectional structure of one of pixels of an imaging device according to a fifth embodiment;

FIG. 28 is a plan view of the planar layout of pixel electrodes and a shield electrode in the imaging device according to the fifth embodiment;

FIG. 29 is a schematic cross-sectional view of the cross-sectional structure of one of pixels of an imaging device according to a sixth embodiment;

FIG. 30 is a schematic cross-sectional view of the cross-sectional structure of pixels of an imaging device according to a seventh embodiment; and

FIG. 31 is a block diagram illustrating the structure of a camera system according to an eighth embodiment.

### DETAILED DESCRIPTION

### Outline of Present Disclosure

An imaging device according to an aspect of the present disclosure includes a pixel electrode, a counter electrode that faces the pixel electrode, a first quantum dot that includes a first core and a first shell and that is located between the pixel electrode and the counter electrode, the first core generating first signal charge, the first shell covering the first core and forming a first heterojunction barrier against the first signal charge, a second quantum dot that includes a second core and a second shell and that is located between the pixel electrode and the counter electrode, the second core generating second signal charge, the second shell covering the second core and forming a second heterojunction barrier against the second signal charge, and a charge accumulator that is electrically connected to the pixel electrode and that accumulates the first signal charge and the second signal charge. The first quantum dot and the second quantum dot are type-ll quantum dots. In a case where a potential difference between the pixel electrode and the counter electrode is a first potential difference, the first signal charge does not pass through the first heterojunction barrier and is held in the first core and the second signal charge passes through the second heterojunction barrier and is collected by the pixel electrode. In a case where the potential difference between the pixel electrode and the counter electrode is a second potential difference which is larger than the first potential difference, the first signal charge passes through the first heterojunction barrier and is collected by the pixel electrode.

As a result, signal charge generated in the first quantum dot and signal charge generated in the second quantum dot can be separately read using a single pixel electrode by adjusting the potential difference between the pixel electrode and the counter electrode, A pixel electrode, therefore, need not be provided for each of the signal charges, and the resolution and sensitivity of the imaging device increase.

An imaging device according to another aspect of the present disclosure includes a pixel electrode, a counter electrode that faces the pixel electrode, a first quantum dot that includes a first core and a first shell and that is located between the pixel electrode and the counter electrode, the first core generating first signal charge, the first shell covering the first core, a second quantum dot that includes a second core and a second shell and that is located between the pixel electrode and the counter electrode, the second core generating second signal charge, the second shell covering the second core, and a charge accumulator that is electrically connected to the pixel electrode and that accumulates the first signal charge and the second signal charge. The first quantum dot is one of a hole confining type-II quantum dot and an electron confining type-II quantum dot. The second quantum dot is the other of the hole confining type-II quantum dot and the electron confining type-II quantum dot.

As a result, since the first and second quantum dots can confine charges of different polarities in the cores thereof, reading timings of signal charges generated in the first and second quantum dots can be easily made different from each other. Signal charge generated in the first quantum dot and signal charge generated in the second quantum dot, therefore, can be separately read using a single pixel electrode, A pixel electrode, therefore, need not be provided for each of the signal charges, and the resolution and sensitivity of the imaging device improve.

In addition, for example, in a case where a potential difference between the pixel electrode and the counter electrode is a first potential difference, the first signal charge need not pass through the first shell and may be held in the first core and the second signal charge may pass through the second shell and be collected by the pixel electrode. In a case where the potential difference between the pixel electrode and the counter electrode is a second potential difference which is larger than the first potential difference, the first signal charge may pass through the first shell and be collected by the pixel electrode.

As a result, signal charge generated in the first quantum dot and signal charge generated in the second quantum dot can be separately read using a single pixel electrode by adjusting the potential difference between the pixel electrode and the counter electrode.

In addition, for example, the second potential difference may be larger than the first potential difference by 0.5 V or more.

As a result, the accuracy of separately reading signal charge increases. More specifically, when the second signal charge is read from the second quantum dot, the accuracy of confining the first signal charge in the first core of the first quantum dot increases. Mixing of the first signal charge and the second signal charge, therefore, is suppressed, and an imaging device with little noise is achieved.

In addition, for example, the imaging device according to the aspect of the present disclosure may further include a voltage supply circuit electrically connected to the counter electrode. The voltage supply circuit may supply, in a first period, a first voltage to the counter electrode such that the potential difference between the pixel electrode and the counter electrode becomes the first potential difference and, in a second period which is different from the first period, a second voltage to the counter electrode such that the potential difference between the pixel electrode and the counter electrode becomes the second potential difference.

As a result, holding and transfer of signal charge can be switched at certain timings by adjusting the potential difference between the pixel electrode and the counter electrode using the voltage supply circuit.

In addition, for example, in a case where the potential difference between the pixel electrode and the counter electrode is monotonously increased from the first potential difference to the second potential difference via a threshold potential difference, an amount of signal charge collected by the pixel electrode may be saturated at a certain value before the potential difference reaches the threshold potential difference and, after the potential difference exceeds the threshold potential difference, increase from the certain value.

As a result, the first signal charge and the second signal charge can be separately read by sequentially applying the first potential difference, which is smaller than the threshold potential difference, and the second potential difference, which is larger than the threshold potential difference.

In addition, for example, a thickness of the first shell may be greater than a thickness of the second shell.

As a result, the heterojunction barrier formed by the first shell can be easily made larger than the heterojunction barrier formed by the second shell.

In addition, for example, a material of the first shell may be different from a material of the second shell.

As a result, the heterojunction barrier formed by the first shell can be easily made larger than the heterojunction barrier formed by the second shell.

In addition, for example, a spectral sensitivity characteristic of the first core may be different from a spectral sensitivity characteristic of the second core.

As a result, imaging based on different spectra can be performed. For example, an image in an infrared region and an image in a visible region can be generated.

In addition, for example, a spectral sensitivity characteristic of the first core may be the same as a spectral sensitivity characteristic of the second core.

As a result, low sensitivity and high sensitivity can be switched by switching reading of signal charge from a photoelectric conversion layer in accordance with the amount of light incident on the imaging device. In other words, a range within which the imaging device can perform photoelectric conversion, that is, a dynamic range, increases.

In addition, a method for driving an imaging device according to another aspect of the present disclosure is a method for driving an imaging device including a photoelectric converter that includes a first quantum dot and a second quantum dot between a pixel electrode and a counter electrode, the first quantum dot including a first core and a first shell, the first core generating first signal charge, the first shell covering the first core, the second quantum dot including a second core and a second shell, the second core generating second signal charge, the second shell covering the second core. The method includes (a) setting a potential difference between the pixel electrode and the counter electrode to a first potential difference, to cause the second signal charge generated in the second core to be collected by the pixel electrode while the first signal charge generated in the first core is held in the first core; and (b) setting the potential difference between the pixel electrode and the counter electrode to a second potential difference which is larger than the first potential difference, to cause the first signal charge in the first core to pass through the first shell and to be collected by the pixel electrode.

As a result, as described above, signal charge generated in the first quantum dot and signal charge generated in the second quantum dot can be separately read using a single pixel electrode by adjusting the potential difference between the pixel electrode and the counter electrode. A pixel electrode, therefore, need not be provided for each of the signal charges, and the resolution and sensitivity of the imaging device improve.

Embodiments will be specifically described hereinafter with reference to the drawings,

The embodiments that will be described hereinafter are general or specific examples. Values, shapes, materials, components, arrangement positions and connection modes of the components, steps, order of the steps, and the like mentioned in the following embodiments are examples, and do not limit the present disclosure. Among the components described in the following description, ones not described in the independent claims will be described as optional components.

The drawings are schematic diagrams and not necessarily exact. Scales, for example, do not match the reality in each of the drawings. In the drawings, substantially the same components are given the same reference numerals, and redundant description is omitted or simplified.

Terms indicating relationships between elements, such as “equal to each other”, terms indicating shapes of elements, such as “square” and “circle”, and ranges of values herein are not exact expressions but substantial expressions that can include errors of, say, several percent.

Terms “above” and “below” herein do not refer to upward (vertically above) and downward (vertically below) in absolute spatial recognition but are defined by relative positional relationships based on order of stacking of layers in a multilayer structure, The terms “above” and “below” will be used not only when two components are arranged with a gap provided therebetween and another component is disposed in the gap but also when two components are arranged in contact with each other.

### First Embodiment

### 1. Circuit Configuration of Imaging Device

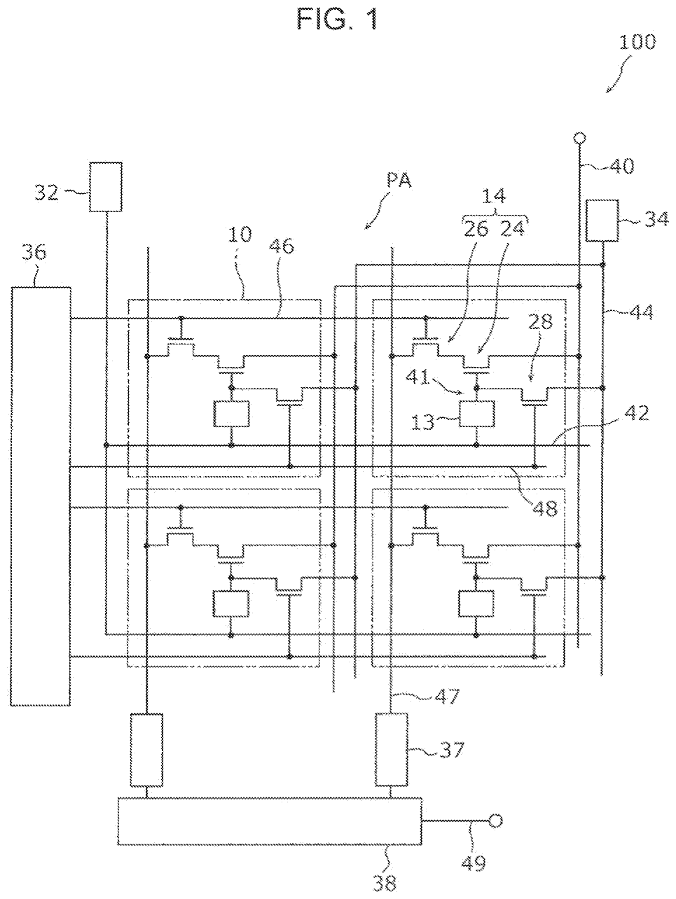

First, the circuit configuration of an imaging device according to a first embodiment will be described with reference to FIG. 1.

FIG. 1 is a circuit diagram illustrating an exemplary circuit configuration of the imaging device according to the present embodiment. An imaging device 100 illustrated in FIG. 1 includes a pixel array PA including pixels 10 arranged in two dimensions. FIG. 1 schematically illustrates an example in which the pixels 10 are arranged in a 2×2 matrix. The number and arrangement of pixels 10 in the imaging device 100 are not limited to the example illustrated in FIG. 1. For example, the imaging device 100 may be a line sensor in which pixels 10 are arranged in a line. Alternatively, the number of pixels 10 included in the imaging device 100 may be one.

Each of the pixels 10 includes a photoelectric conversion unit 13 and a signal detection circuit 14. The photoelectric conversion unit 13 receives incident light and generates a signal. The photoelectric conversion unit 13 need not be an independent element for each of the pixels 10, and a part of the photoelectric conversion unit 13, for example, may be shared by two or more pixels 10. The signal detection circuit 14 detects signal generated by the photoelectric conversion unit 13. In this example, the signal detection circuit 14 includes a signal detection transistor 24 and an address transistor 26. The signal detection transistor 24 and the address transistor 26 are typically field-effect transistors (FETs). Here, n-channel metal-oxide-semiconductor field-effect transistors (MOSFETs) are used as an example of the signal detection transistor 24 and the address transistor 26. Transistors such as the signal detection transistor 24, the address transistor 26, and a reset transistor 28, which will be described later, each include a control terminal, an input terminal, and an output terminal. The control terminal is, for example, a gate. The input terminal is, for example, either a drain or a source and may be, for example, the drain. The output terminal is another of the drain and the source and may be, for example, the source.

As schematically illustrated in FIG. 1, the control terminal of the signal detection transistor 24 is electrically connected to the photoelectric conversion unit 13. Signal charge generated by the photoelectric conversion unit 13 is accumulated in a charge accumulation node 41 between the gate of the signal detection transistor 24 and the photoelectric conversion unit 13. Here, the signal charge is holes or electrons. The charge accumulation node 41 is an example of a charge accumulator and also called a “floating diffusion node”. The charge accumulation node 41 will be also referred to as a “charge accumulation region” herein. Details of the structure of the photoelectric conversion unit 13 will be described later.

The photoelectric conversion unit 13 of each of the pixels 10 is also connected to a bias control line 42. In the configuration illustrated in FIG. 1, the bias control line 42 is connected to a voltage supply circuit 32. The voltage supply circuit 32 is configured to be able to supply at least two types of voltage. During the operation of the imaging device 100, the voltage supply circuit 32 supplies a certain voltage to the photoelectric conversion unit 13 via the bias control line 42. The voltage supply circuit 32 is not limited to a certain power supply circuit and may be a circuit that generates the certain voltage or a circuit that converts a voltage supplied from another power supply into the certain voltage. As will be described in detail later, movement of signal charge from the photoelectric conversion unit 13 to the charge accumulation node 41 is controlled by switching the voltage supplied from the voltage supply circuit 32 to the photoelectric conversion unit 13 between different values. An example of the operation of the imaging device 100 will be described later.

The pixels 10 are each connected to a power supply line 40 used to supply a power supply voltage VDD. As illustrated in FIG. 1, the input terminal of the signal detection transistor 24 is connected to the power supply line 40. When the power supply line 40 functions as a source follower power supply, the signal detection transistor 24 amplifies a signal generated by the photoelectric conversion unit 13 and outputs the amplified signal.

The input terminal of the address transistor 26 is connected to the output terminal of the signal detection transistor 24. The output terminal of the address transistor 26 is connected to one of vertical signal lines 47 provided for columns of the pixel array PA. The control terminal of the address transistor 26 is connected to an address control line 46. An output of the signal detection transistor 24 can be selectively read by a corresponding vertical signal line 47 by controlling potential of the address control line 46.

In the example illustrated in FIG. 1, the address control line 46 is connected to a vertical scanning circuit 36. The vertical scanning circuit 36 is also called a “row scanning circuit”. The vertical scanning circuit 36 applies a certain voltage to the address control lines 46 to select the pixels 10 arranged in each of rows in units of rows. As a result, reading of signals from the selected pixels 10 and resetting of the charge accumulation nodes 41 are performed.

The vertical signal lines 47 are main signal lines for transferring pixel signals from the pixel array PA to peripheral circuits. Column signal processing circuits 37 are connected to the vertical signal lines 47. The column signal processing circuits 37 are also called “row signal accumulation circuits”. The column signal processing circuits 37 perform, for example, noise suppression signal processing, which is typified by correlated double sampling, and analog-to-digital conversion. As illustrated in FIG. 1, each of the column signal processing circuits 37 is provided for one of the columns of the pixels 10. A horizontal signal reading circuit 38 is connected to the column signal processing circuits 37. The horizontal signal reading circuit 38 is also called a “column scanning circuit”. The horizontal signal reading circuit 38 sequentially reads signals from the column signal processing circuits 37 and outputs the signals to a horizontal common signal line 49.

In the configuration illustrated in FIG. 1, the pixels 10 each include a reset transistor 28. As with the signal detection transistor 24 and the address transistor 26, for example, the reset transistor 28 is an FET. In the following description, an example in which an n-channel MOSFET is used as the reset transistor 28 will be described unless otherwise specified. As illustrated in FIG. 1, the reset transistor 28 is connected between a reset voltage line 44 for supplying a reset voltage Vr and the charge accumulation node 41. The control terminal of the reset transistor 28 is connected to a reset control line 48. Potential of the charge accumulation node 41 can be reset to the reset voltage Vr by controlling potential of the reset control line 48. In this example, the reset control line 48 is connected to the vertical scanning circuit 36. The pixels 10 arranged in each of the rows, therefore, can be reset in units of rows by applying a certain voltage to the reset control lines 48 using the vertical scanning circuit 36.

In this example, the reset voltage line 44 for supplying the reset voltage Vr to the reset transistor 28 is connected to a reset voltage source 34. The reset voltage source 34 is also called a “reset voltage supply circuit”. The reset voltage source 34 may be configured to be able to supply the certain reset voltage Vr to the reset voltage line 44 during the operation of the imaging device 100 and, as with the voltage supply circuit 32, is not limited to a certain power supply circuit. The voltage supply circuit 32 and the reset voltage source 34 may be parts of the same voltage supply circuit or may be separate voltage supply circuits. One or both of the voltage supply circuit 32 and the reset voltage source 34 may be a part of the vertical scanning circuit 36. Alternatively, a control voltage from the voltage supply circuit 32 and/or the reset voltage Vr from the reset voltage source 34 may be supplied to the pixels 10 through the vertical scanning circuit 36.

The power supply voltage VDD of the signal detection circuit 14 may be used as the reset voltage Vr, instead, In this case, a voltage supply circuit (not illustrated in FIG. 1) that supplies a power supply voltage to the pixels 10 and the reset voltage source 34 can be integrated with each other. Because the power supply line 40 and the reset voltage line 44 can also be integrated with each other, wiring in the pixel array PA can be simplified. When the reset voltage Vr is different from the power supply voltage VDD supplied by the signal detection circuit 14, however, the imaging device 100 can perform more flexible control.

### 2. Cross-Sectional Structure of Pixels

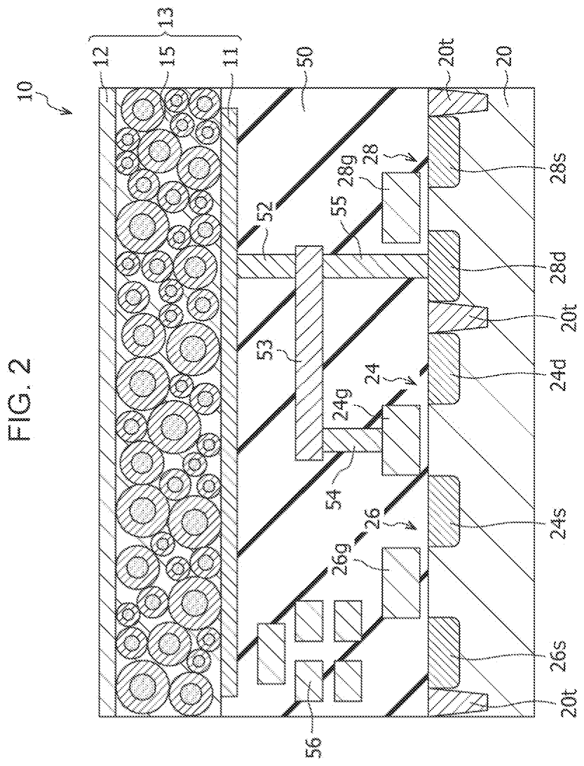

Next, the cross-sectional structure of the pixels 10 of the imaging device 100 according to the present embodiment will be described with reference to FIG. 2.

FIG. 2 is a schematic cross-sectional view of the cross-sectional structure of one of the pixels 10 of the imaging device 100 according to the present embodiment. In the structure illustrated in FIG. 2, the signal detection transistor 24, the address transistor 26, and the reset transistor 28 are formed on a semiconductor substrate 20. The semiconductor substrate 20 is not limited to a substrate entirely composed of a semiconductor. The semiconductor substrate 20 may be an insulating substrate having a surface on which a photosensitive area and a semiconductor layer are provided, instead. An example in which a p-type silicon (Si) substrate is used as the semiconductor substrate 20 will be described hereinafter.

The semiconductor substrate 20 includes impurity regions 26s, 24s, 24d, 28d, and 28s and element isolation regions 20t for electrically isolating the pixels 10 with one another. The impurity regions 26s, 24s, 24d, 28d, and 28s are n-type regions. An element isolation region 20t is also provided between the impurity regions 24d and 28d. The element isolation regions 20t are formed, for example, by implanting an acceptor through ion implantation under certain implantation conditions.

The impurity regions 26s, 24s, 24d, 28d, and 28s are, for example, an impurity diffusion layer formed in the semiconductor substrate 20. As schematically illustrated in FIG. 2, the signal detection transistor 24 includes the impurity regions 24s and 24d and a gate electrode 24g. The gate electrode 24g is composed of a conductive material. The conductive material is, for example, polysilicon that has conductivity as a result of impurity doping, but may be a metal material, instead. The impurity region 24s functions, for example, as a source region of the signal detection transistor 24. The impurity region 24d functions, for example, as a drain region of the signal detection transistor 24. A channel region of the signal detection transistor 24 is formed between the impurity regions 24s and 24d.

Similarly, the address transistor 26 includes impurity regions 26s and 24s and a gate electrode 26g. The gate electrode 26g is composed of a conductive material. The conductive material is, for example, polysilicon that has conductivity as a result of impurity doping, but may be a metal material. The impurity region 26g is connected to one of the address control lines 46, which are not illustrated in FIG. 2. In this example, the signal detection transistor 24 and the address transistor 26 are electrically connected to each other by sharing the impurity region 24s. The impurity region 24s functions, for example, as a drain region of the address transistor 26. The impurity region 26s functions, for example, as a source region of the address transistor 26. The impurity region 26s is connected to one of the vertical signal lines 47, which are not illustrated in FIG. 2. The impurity region 24s need not be shared by the signal detection transistor 24 and the address transistor 26. More specifically, the source region of the signal detection transistor 24 and the drain region of the address transistor 26 may be separated from each other on the semiconductor substrate 20 and electrically connected to each other via wiring layers 56 provided in an interlayer insulating layer 50.

The reset transistor 28 includes impurity regions 28d and 28s and a gate electrode 28g. The gate electrode 28g is composed, for example, of a conductive material. The conductive material is, for example, polysilicon that has conductivity as a result of impurity doping, but may be a metal material. The impurity region 28g is connected to one of the reset control lines 48, which are not illustrated in FIG. 2. The impurity region 28s functions, for example, as a source region of the reset transistor 28. The impurity region 28s is connected to one of the reset voltage lines 44, which are not illustrated in FIG. 2, The impurity region 28d functions, for example, as a drain region of the reset transistor 28.

The interlayer insulation layer 50 is provided on the semiconductor substrate 20 in such a way as to cover the signal detection transistor 24, the address transistor 26, and the reset transistor 28. The interlayer insulation layer 50 is composed, for example, of an insulating material such as silicon dioxide. As illustrated in FIG. 2, the wiring layers 56 are provided in the interlayer insulation layer 50. The wiring layers 56 are typically composed of a metal such as copper. The wiring layers 56 may include, for example, signal lines such as the vertical signal lines 47 or power supply lines as a part thereof. The number of insulating layers in the interlayer insulation layer 50 and the number of layers included in the wiring layers 56 provided in the interlayer insulation layer 50 may be set as desired and are not limited to the example illustrated in FIG. 2.

As illustrated in FIG. 2, a plug 52, a wire 53, and contact plugs 54 and 55 are also provided in the interlayer insulation layer 50. The wire 53 may be a part of the wiring layers 56. The plug 52, the wire 53, and the contact plugs 54 and 55 are each composed of a conductive material. The plug 52 and the wire 53, for example, are composed of a metal such as copper. The contact plugs 54 and 55, for example, are composed of polysilicon that has conductivity as a result of impurity doping. The plug 52, the wire 53, and the contact plugs 54 and 55 may be composed of the same material or different materials.

The plug 52, the wire 53, and the contact plug 54 constitute at least a part of the charge accumulation node 41 between the signal detection transistor 24 and the photoelectric conversion unit 13. In the structure illustrated in FIG. 2, the gate electrode 24g of the signal detection transistor 24, the plug 52, the wire 53, the contact plugs 54 and 55, and the impurity region 28d, which is either the source region or the drain region of the reset transistor 28 function as a charge accumulation region for accumulating signal charge collected by a pixel electrode 11 of the photoelectric conversion unit 13.

More specifically, the pixel electrode 11 of the photoelectric conversion unit 13 is connected to the gate electrode 24g of the signal detection transistor 24 via the plug 52, the wire 53, and the contact plug 54. In other words, the gate of the signal detection transistor 24 is electrically connected to the pixel electrode 11. The pixel electrode 11 is also connected to the impurity region 28d via the plug 52, the wire 53, and the contact plug 55.

As the pixel electrode 11 collects signal charge, a voltage according to the amount of signal charge accumulated in the charge accumulation region is applied to the gate of the signal detection transistor 24. The signal detection transistor 24 amplifies the voltage. The voltage amplified by the signal detection transistor 24 is selectively read by the address transistor 26 as signal voltage.

The photoelectric conversion unit 13 is arranged above the interlayer insulation layer 50. The pixels 10 arranged in two dimensions when the semiconductor substrate 20 is viewed as a plan form the photosensitive area. The photosensitive area is also called a “pixel area”, A distance between two adjacent pixels 10, that is, pixel pitch, may be, say, about 2 μm.

### 3. Configuration of Photoelectric Conversion Unit

A specific configuration of the photoelectric conversion unit 13 will be described hereinafter.

As illustrated in FIG. 2, the photoelectric conversion unit 13 includes the pixel electrode 11, a counter electrode 12, and a photoelectric conversion layer 15 provided between the pixel electrode 11 and the counter electrode 12. The counter electrode 12, the photoelectric conversion layer 15, and the pixel electrode 11 are arranged in this order from a side of the imaging device 100 on which light is incident in the present embodiment.

In the example illustrated in FIG. 2, the counter electrode 12 and the photoelectric conversion layer 15 are formed over a plurality of pixels 10. The pixel electrode 11 is provided for each of the pixels 10. The pixel electrode 11 of one of the pixels 10 is electrically isolated from the pixel electrode 11 of another pixel 10 because these pixel electrodes 11 are spatially separated from each other. At least one of the counter electrode 12 or the photoelectric conversion layer 15 may be separately provided for each of the pixels 10.

### 3-1. Pixel Electrode and Counter Electrode

The pixel electrode 11 is an electrode for reading signal charge generated by the photoelectric conversion unit 13. There is at least one pixel electrode 11 for each of the pixels 10. The pixel electrode 11 is electrically connected to the gate electrode 24g of the signal detection transistor 24 and the impurity region 28d.

The pixel electrode 11 is composed of a conductive material. The conductive material is, for example, a metal such as aluminum or copper, a metal nitride, or polysilicon that has conductivity as a result of impurity doping.

The counter electrode 12 is, for example, a transparent electrode composed of a transparent conductive material. The counter electrode 12 is arranged on a side of the photoelectric conversion layer 15 on which light is incident. Light that has passed through the counter electrode 12, therefore, is incident on the photoelectric conversion layer 15. Light detected by the imaging device 100 is not limited to light within a wavelength range of visible light. For example, the imaging device 100 may detect infrared light or ultraviolet light. The wavelength range of visible light is, for example, 380 nm to 780 nm.

A term “transparent” herein means that an object passes at least a part of light within a wavelength range to be detected and that the object need not pass light over the entirety of the wavelength range of visible light. A term “light” herein refers to electromagnetic waves in general including infrared light and ultraviolet light.

The counter electrode 12 is composed, for example, of a transparent conducting oxide (TCO) such as ITO, IZO, AZO, FTO, SnO2, TiO₂, or ZnO₂. The voltage supply circuit 32 illustrated in FIG. 1 is connected to the counter electrode 12. By adjusting voltage applied by the voltage supply circuit 32 to the counter electrode 12, a potential difference between the counter electrode 12 and the pixel electrode 11 can be set and kept at a desired value.

As described with reference to FIG. 1, the counter electrode 12 is connected to the bias control line 42 connected to the voltage supply circuit 32. The counter electrode 12 is formed over a plurality of pixels 10. The voltage supply circuit 32, therefore, can collectively apply a desired control voltage to the plurality of pixels 10 via the bias control lines 42. Alternatively, the counter electrode 12 may be separately provided for each of the pixels 10 insofar as the voltage supply circuit 32 can apply a desired control voltage.

As described in detail later, the voltage supply circuit 32 supplies different voltages to the counter electrode 12 between an exposure period and a non-exposure period. The “exposure period” herein refers to a period for which signal charge generated as a result of photoelectric conversion is accumulated in the photoelectric conversion layer 15 or the charge accumulation region and may be called a “charge accumulation period”, instead. Periods in which the imaging device 100 operates and that are other than exposure periods will be referred to as “non-exposure periods” herein. The non-exposure periods are not limited to periods in which incidence of light on the photoelectric conversion unit 13 is prevented and may include periods in which light is radiated onto the photoelectric conversion unit 13. The non-exposure periods also include periods in which signal charge is unintentionally accumulated in the charge accumulation region due to parasitic sensitivity.

When the voltage supply circuit 32 controls potential of the counter electrode 12 against potential of the pixel electrode 11, the pixel electrode 11 can collect, as signal charge, either holes or electrons of hole-electron pairs generated in the photoelectric conversion layer 15 as a result of photoelectric conversion. When holes are used as signal charge, for example, the pixel electrode 11 can selectively collect the holes by making the potential of the counter electrode 12 higher than that of the pixel electrode 11. A case where holes are used as signal charge will be described hereinafter. It is needless to say that electrons may be used as signal charge, and in this case, the potential of the counter electrode 12 may be made lower than that of the pixel electrode 11. When an appropriate bias voltage is applied between the counter electrode 12 and the pixel electrode 11, the pixel electrode 11, which faces the counter electrode 12, collects either positive or negative charge generated in the photoelectric conversion layer 15 as a result of photoelectric conversion.

In the present embodiment, at least one of the signal detection circuit 14 or the voltage supply circuit 32 can be integrated on the same substrate as the photoelectric conversion unit 13. Alternatively, at least one of the signal detection circuit 14 or the voltage supply circuit 32 may be formed on a substrate different from the one on which the photoelectric conversion unit 13 is formed.

### 3-2. Photoelectric Conversion Layer

The photoelectric conversion layer 15 is located between the pixel electrode 11 and the counter electrode 12 and generates signal charge through photoelectric conversion. That is, the photoelectric conversion layer 15 absorbs photons and generates photo-charge. Signal charge is photo-charge obtained as a result of photoelectric conversion and is either holes or electrons.

The photoelectric conversion layer 15 includes quantum dots. Each of the quantum dots is a core-shell quantum dot. A core-shell quantum dot includes a core composed of a semiconductor having a size of several nanometers to tens of nanometers and a shell composed of a semiconductor having an energy level different from that of the core. The shell covers the core.

The quantum dots included in the photoelectric conversion layer 15 are type-II quantum dots. In a type-II quantum dot, either a hole or an electron is confined in a core because of a difference between energy levels of the core and a shell. That is, there are two types of type-II quantum dot, namely a hole confining quantum dot and an electron confining quantum dot.

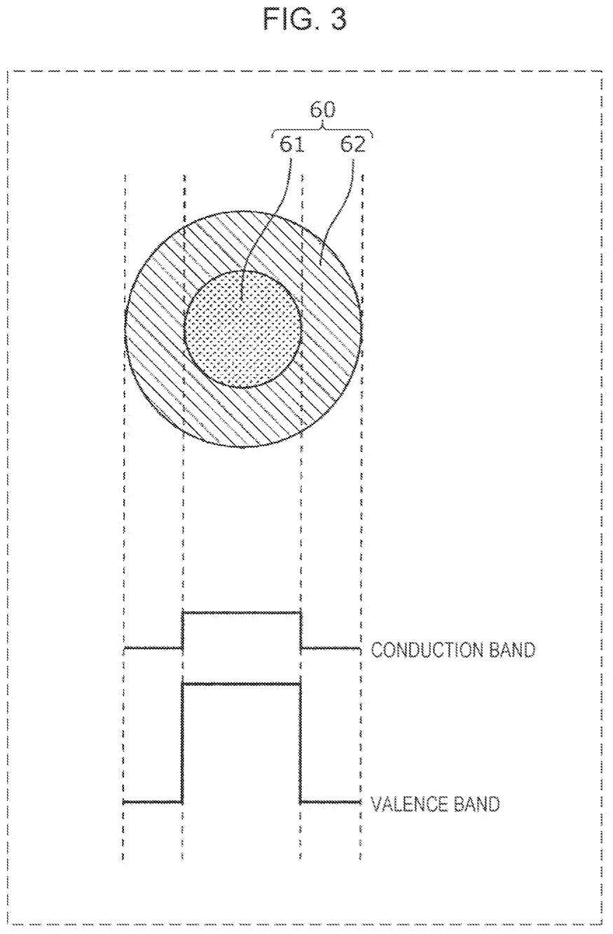

FIG. 3 is a schematic diagram illustrating the structure and energy levels of a hole confining type-II quantum dot. As illustrated in FIG. 3, a quantum dot 60 includes a core and a shell 62. The core 61 is coated by the shell 62. That is, the shell 62 is in contact with and covers the entirety of an outer surface of the core 61.

A valence band level of the core 61 is higher than that of the shell 62. Since a hole moves in a valence band in a direction in which an energy level is higher than that of an electron, which is a negative charge, the shell 62 serves as a barrier for a hole in the core 61. That is, the shell 62 forms a heterojunction barrier against a hole generated in the core 61. As a result, the hole generated in the core 61 is confined in the core 61.

In addition, a conduction band level of the core 61 is higher than that of the shell 62. Since an electron moves in a conduction band in a direction in which an energy level is lower than that of an electron, which is a negative charge, the shell 62 does not serve as a barrier for an electron in the core 61. That is, the shell 62 does not form a heterojunction barrier against an electron generated in the core 61. As a result, the electron generated in the core 61 moves to the shell 62 without being confined in the core 61.

Since the quantum dot 60 is a hole confining type-II quantum dot as described above, a hole generated in the core 61 keeps being confined in the core 61, and an electron generated in the core 61 moves to the shell 62. In an aggregate of quantum dots 60, electrons can easily move between shells 62 of adjacent quantum dots 60.

When an electric field is applied to the quantum dot 60, a hole confined in the core 61 passes through the shell 62 due to a tunneling effect and stochastically moves out of the quantum dot 60 or to the core 61 of another quantum dot 60. As the electric field applied to the quantum dot 60 becomes stronger, a probability that the hole passes through the shell 62 increases. When the electric field is stronger than a certain threshold, the hole in the core 61 can substantially freely move between the shells 62.

The core 61 is composed, for example, of cadmium telluride (CdTe), and the shell 62 is composed, for example, of zinc sulfide (ZnS). The quantum dot 60 thus becomes a hole confining type-II quantum dot. Materials of the core 61 and the shell 62 are not particularly limited insofar as a relationship between energy levels illustrated in FIG. 3 is satisfied.

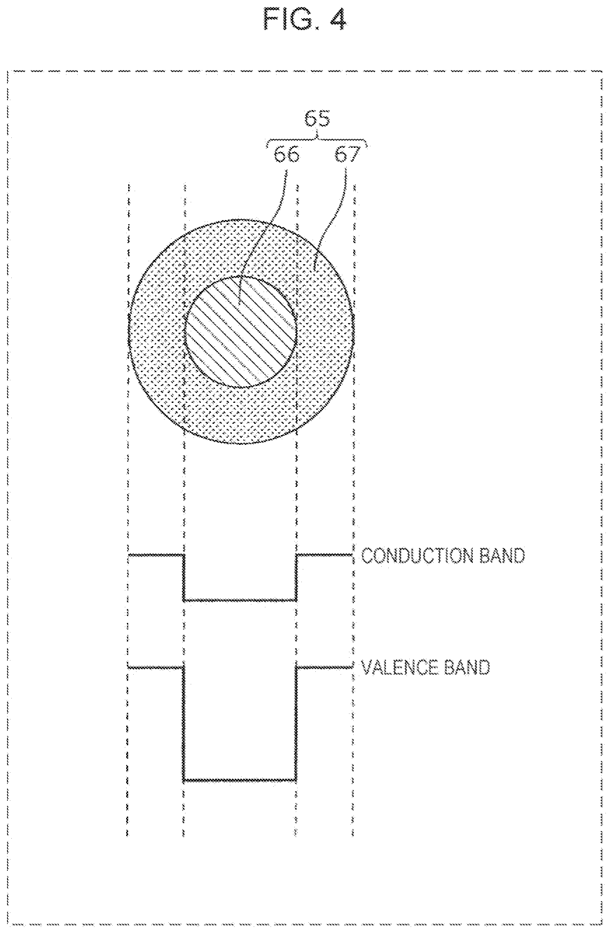

FIG. 4 is a schematic diagram illustrating the structure and energy levels of an electron confining type-II quantum dot. As illustrated in FIG. 4, a quantum dot 65 includes a core 66 and a shell 67. The core 66 is coated by the shell 67. That is, the shell 67 is in contact with and covers the entirety of an outer surface of the core 66.

A conduction band level of the core 66 is lower than that of the shell 67. The shell 67, therefore, serves as a barrier for an electron in the core 66. That is, the shell 67 forms a heterojunction barrier against an electron generated in the core 66. As a result, the electron generated in the core 66 is confined in the core 66.

In addition, a valence band level of the core 66 is lower than that of the shell 67. The shell 67, therefore, does not serve as a barrier for a hole in the core 66. As a result, a hole generated in the core 66 moves to the shell 67 without being confined in the core 66.

Since the quantum dot 65 is an electron confining type-II quantum dot as described above, the electron generated in the core 66 keeps being confined in the core 66, and the hole generated in the core 66 moves to the shell 67. In an aggregate of quantum dots 65, holes can easily move between shells 67 of adjacent quantum dots 65.

When an electric field is applied to the quantum dot 65, the electron confined in the core 66 passes through the shell 67 due to a tunneling effect and stochastically moves out of the quantum dot 65 or to the core 66 of another quantum dot 65. As the electric field applied to the quantum dot 65 becomes stronger, a probability that the electron passes through the shell 67 increases. When the electric field is stronger than a certain threshold, the electron in the core 66 can substantially freely move between the shells 67.

The core 66 is composed, for example, of cadmium zinc sulfide (CdZnS), and the shell 67 is composed, for example, of zinc selenide (ZnSe). The quantum dot 65 thus becomes an electron confining type-II quantum dot. Materials of the core 66 and the shell 67 are not particularly limited insofar as a relationship between energy levels illustrated in FIG. 4 is satisfied.

The photoelectric conversion layer 15 according to the present embodiment may include quantum dots 60 or quantum dots 65. When the pixel electrode 11 collects holes, for example, the photoelectric conversion layer 15 includes the hole confining quantum dots 60. When the pixel electrode 11 collects electrons, the photoelectric conversion layer 15 includes the electron confining quantum dots 65.

In the following description, a case where the pixel electrode 11 collects holes, that is, the photoelectric conversion layer 15 includes the hole confining quantum dots 60, will be taken as an example.

The quantum dots 60 exhibit absorbance and generate photo-charge. The quantum dots 60 achieve continuous absorption mainly deriving from a semiconductor band structure of the cores 61 and resonant absorption at certain wavelengths based on a quantum confinement effect.

Wavelengths at which resonant absorption is observed are called “resonant wavelengths”. The resonant wavelength of each quantum dot 60 depends on the materials of the corresponding core 61 and shell 62 and the size of the core 61. When materials of the core 61 and the shell 62 are the same, for example, the resonant wavelength becomes shorter as the core 61 becomes smaller.

The spread of the resonant wavelength of each quantum dot 60 is usually 0.1 nm or shorter. It is difficult to fabricate a large number of quantum dots 60 having exactly the same size and the same material. Even if quantum dots 60 are fabricated under the same fabrication conditions, some degree of variation is caused. An aggregate of quantum dots 60 included within a range of the variation will be referred to as a “quantum dot group”. The resonant wavelength of a quantum dot group usually has a width of several nanometers to tens of nanometers from a peak thereof.

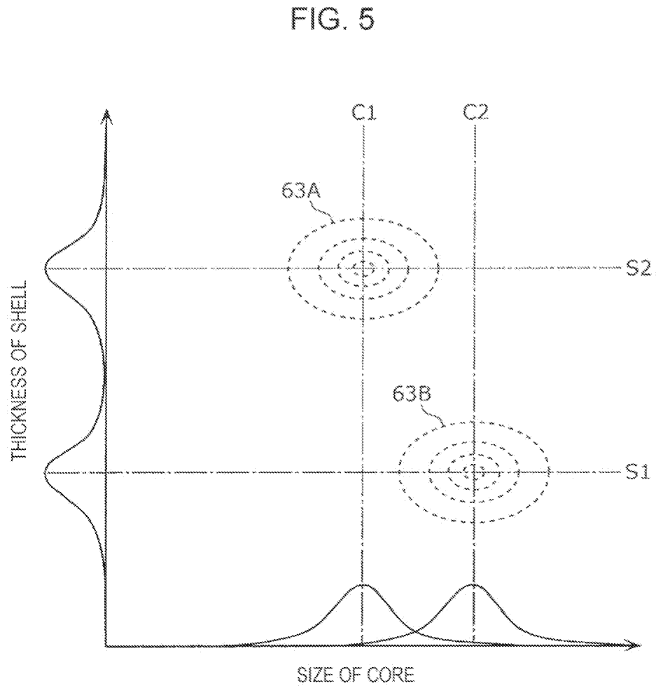

FIG. 5 is a diagram illustrating the distribution of quantum dot groups fabricated by a general manufacturing method. In FIG. 5, a horizontal axis represents the size of cores, and a vertical axis represents the thickness of shells.

FIG. 5 illustrates two quantum dot groups 63A and 63B. Sizes of cores of quantum dots included in the quantum dot group 63A are within a certain range from a value C1, and thicknesses of shells of the quantum dots included in the quantum dot group 63A are within a certain range from a value S2. In the quantum dot group 63A, for example, an average of the sizes of the cores is C1, and an average of the thicknesses of the shells is S2.

Sizes of cores of quantum dots included in the quantum dot group 63B are within a certain range from a value C2, and thicknesses of shells of the quantum dots included in the quantum dot group 63B are within a certain range from a value S1. In the quantum dot group 63B, for example, an average of the sizes of the cores is C2, and an average of the thicknesses of the sheds is S1. That is, in the quantum dot group 63B, the average of the sizes of the cores is larger and the average of the thicknesses of the shells is smaller than in the quantum dot group 63A.

Quantum dot groups whose sizes of cores and thicknesses of shells are different from each other can be fabricated by appropriately adjusting materials and a fabrication method. For example, a quantum dot group in which an average of sizes of cores is C1 and an average of thicknesses of shells is S1 and a quantum dot group in which an average of sizes of cores is C2 and an average of thicknesses of shells is S2 can be fabricated.

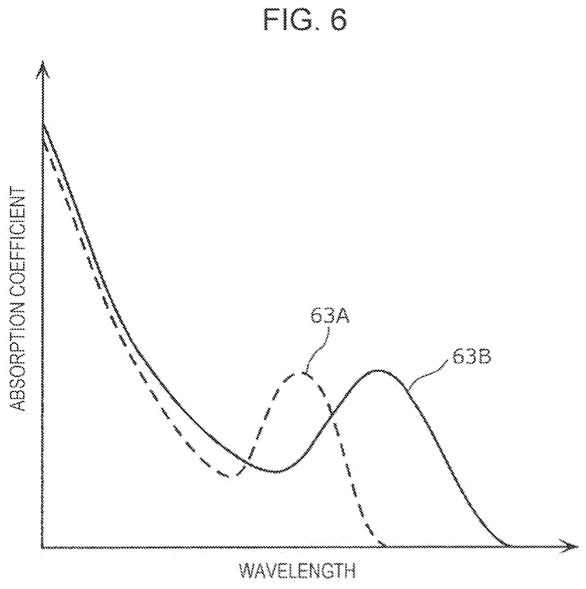

In the present embodiment, the photoelectric conversion layer 15 includes the quantum dot groups 63A and 63B illustrated in FIG. 5. The number of quantum dots included in the quantum dot group 63A and the number of quantum dots included in the quantum dot group 63B are substantially the same. The quantum dot groups 63A and 63B have different spectral sensitivity characteristics. More specifically, absorption spectra are different from each other as illustrated in FIG. 6.

FIG. 6 is a diagram illustrating absorption spectra of quantum dot groups whose peaks of resonant frequencies are different from each other. In FIG. 6, a horizontal axis represents wavelength, and a vertical axis represents an absorption coefficient. The higher the absorption coefficient, the larger the amount of light having a corresponding wavelength absorbed and the larger the amount of signal charge generated.

The absorption spectra of the quantum dot groups 63A and 63B partly overlap with each other but do not perfectly match. An average of resonant wavelengths in the quantum dot group 63A and an average of resonant wavelengths in the quantum dot group 63B, for example, are different from each other.

A difference in the absorption spectrum can be achieved, for example, by making the average of the sizes of the cores in the quantum dot group 63A and the average of the sizes of the cores in the quantum dot group 63B different from each other. Alternatively, the difference in the absorption spectrum may be achieved by using different materials for the quantum dot groups 63A and 63B.

In general, a resonant wavelength in an absorption spectrum of a core tends to be shorter as a band gap of a semiconductor of which the core is composed becomes larger. A band gap of a semiconductor of which the cores in the quantum dot group 63A are composed may be larger than a band gap of a semiconductor of which the cores in quantum dot group 63B are composed. Sizes of the band gap can be controlled by changing materials of the semiconductors. A band gap of bulk cadmium sulfide (CdS) is about 2.42 eV, and a band gap of bulk cadmium selenide (CdSe) is about 1.73 eV. A band gap of bulk lead sulfide (PbS) is about 0.37 eV. A semiconductor core containing cadmium as a component is suitable to achieve a resonant wavelength in a visible range, and a semiconductor core containing lead as a component is suitable to achieve a resonant wavelength in an infrared range.

In the case of a mixed-crystal semiconductor such as cadmium selenide sulfide (CdSxSe₁₋ₓ), on the other hand, a band gap can be changed by adjusting a composition ratio x.

In the present embodiment, the average C1 of the sizes of the cores in the quantum dot group 63A is smaller than the average C2 of the sizes of the cores in the quantum dot group 63B as illustrated in FIG. 5. As a result, as illustrated in FIG. 6, the quantum dot group 63A has a resonant wavelength in a band shorter than a band of the resonant wavelength of the quantum dot group 63B. For example, the quantum dot group 63A has a high absorption coefficient for visible light, and the quantum dot group 63B has a high absorption coefficient for infrared light. That is, the quantum dot group 63A is sensitive to visible light, and the quantum dot group 63B is sensitive to infrared light.

The average S2 of the thicknesses of the shells in the quantum dot group 63A is larger than the average S1 of the thicknesses of the shells in the quantum dot group 63B. Since the shells form heterojunction barriers against electrons held by the cores, the heterojunction barriers become larger as the shells become thicker. That is, a threshold voltage necessary for an electron held by a core to pass through a shell due to a tunneling effect becomes larger as the shell becomes thicker. More specifically, a threshold voltage for the quantum dot group 63A is larger than one for the quantum dot group 63B.

A difference in the threshold voltage between the quantum dot groups 63A and 63B may be achieved by using different materials for the cores and the shells. More specifically, the threshold voltages for the quantum dot groups 63A and 63B become different from each other by making differences between energy levels of the cores and the shells different from each other, For example, the difference between the energy levels of the cores and the shells in the quantum dot group 63A is made larger than the difference between the energy levels of the cores and the shells in the quantum dot group 63B. As a result, the threshold voltage for the quantum dot group 63A becomes larger than that for the quantum dot group 63B.

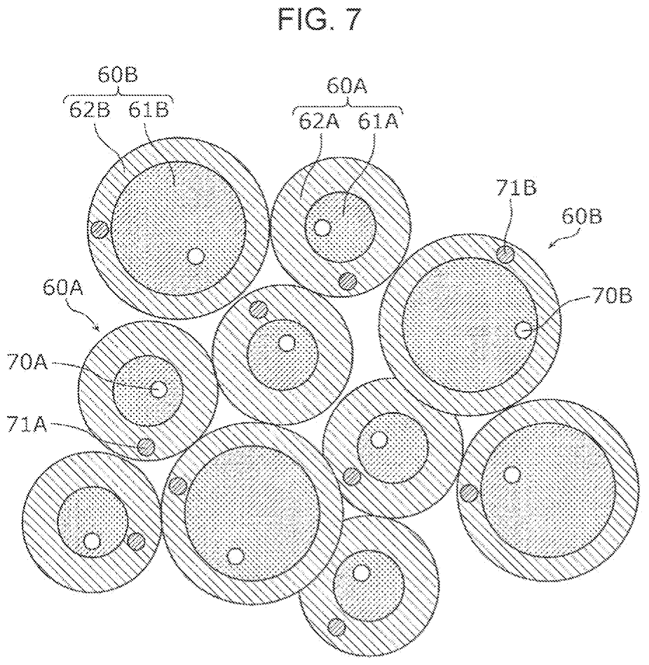

FIG. 7 is a schematic diagram illustrating the structure of the photoelectric conversion layer 15 in the imaging device 100 and charge generated during exposure according to the present embodiment. FIG. 7 schematically illustrates quantum dots 60A and 60B included in the photoelectric conversion layer 15.

Each of the quantum dots 60A is an example of a first quantum dot and included in the quantum dot group 63A. The quantum dots 60A each include a core 61A and a shell 62A, The core 61A is an example of a first core that generates first signal charge. The shell 62A is an example of a first shell that covers the core 61A and forms a first heterojunction barrier against the first signal charge generated in the core 61A. The quantum dots 60A are hole confining type-H quantum dots. As illustrated in FIG. 7, holes 70A generated in the cores 61A are held in the cores 61A as signal charge, whereas electrons 71A move to the shells 62A.

Each of the quantum dots 60B is an example of a second quantum dot and included in the quantum dot group 63B. The quantum dots 60B each include a core 61B and a shell 62B. The core 61B is an example of a second core that generates second signal charge. The shell 62B is an example of a second shell that covers the core 61B and forms a second heterojunction barrier against the second signal charge generated in the core 61B. The quantum dots 60B are hole confining type-II quantum dots. As illustrated in FIG. 7, holes 70B generated in the cores 61B are held in the cores 61B as signal charge, whereas electrons 71B move to the shells 62B.

In the photoelectric conversion layer 15, for example, the quantum dots 60A and 60B are in close proximity to one another. The photoelectric conversion layer 15 may further contain a charge transportation material and a strength retention material.

In the present embodiment, the second heterojunction barriers formed by the shells 62B are smaller than the first heterojunction barriers formed by the shells 62A. When a potential difference between the pixel electrode 11 and the counter electrode 12 is a first potential difference, therefore, the holes 70A do not pass through the first heterojunction barriers formed by the shells 62A and are held in the cores 61A, and the holes 70B pass through the second heterojunction barriers formed by the shells 62B and are collected by the pixel electrode 11. When the potential difference between the pixel electrode 11 and the counter electrode 12 is a second potential difference, which is larger than the first potential difference, the holes 70A pass through the first heterojunction barriers formed by the shells 62A and are collected by the pixel electrode 11. At this time, the second potential difference is larger than the first potential difference by, for example, 0.5 V or more. The second potential difference may be larger than the first potential difference by 1 V or more, instead.

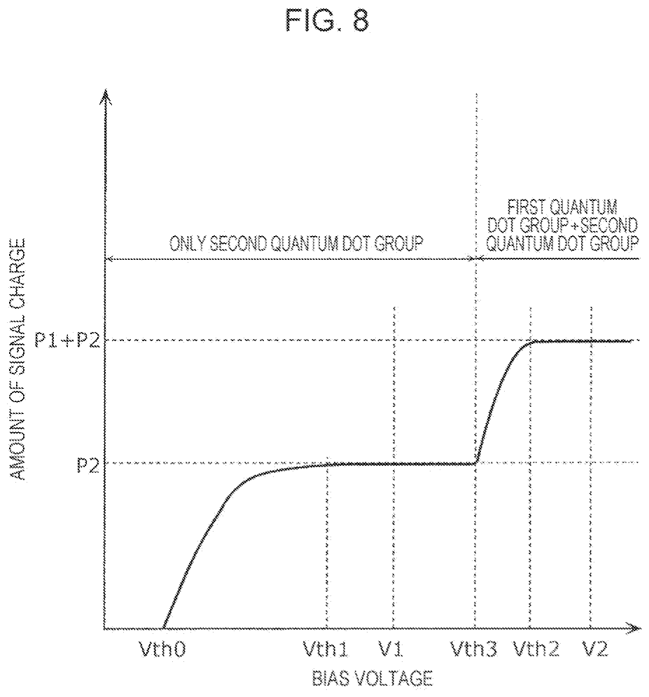

FIG. 8 is a diagram illustrating a relationship between the amount of signal charge generated by the photoelectric conversion layer 15 and bias voltage according to the present embodiment. In FIG. 8, a horizontal axis represents the bias voltage applied to the counter electrode 12, that is, more specifically, the potential difference between the pixel electrode 11 and the counter electrode 12. A vertical axis represents the amount of signal charge collected by the pixel electrode 11, that is, more specifically, the number of holes.

As illustrated in FIG. 8, when the bias voltage exceeds a threshold voltage Vth0, holes 70B held in the cores 61B of some quantum dots 60B included in the photoelectric conversion layer 15 pass through the shells 62B. As the bias voltage increases from the threshold voltage Vth0, the number of holes 70B that pass through the shells 62B increases, and the amount of signal charge accordingly increases.

When the bias voltage reaches the threshold voltage Vth1, the holes 70B can pass through the shells 62B of substantially all the quantum dots 60B included in the photoelectric conversion layer 15, that is, the holes 70B can essentially freely move. In other words, the threshold voltage Vth1 corresponds to the threshold voltage for the quantum dot group 63B.

The threshold volage Vth1 depends on the thickness of the shells 62B of the quantum dots 60B and a difference between the energy levels of the cores 61B and the shells 62B. For example, the threshold voltage Vth1 becomes higher as the shells 62B become thicker. In addition, the threshold voltage Vth1 becomes higher as the difference between the energy levels of the cores 61B and the shells 62B becomes larger. This holds for the quantum dots 60A.

After the bias voltage exceeds the threshold voltage Vth1, the amount of signal charge is saturated until the bias voltage reaches a threshold voltage Vth3, which is an example of a threshold potential difference, An amount P2 of signal charge in a saturated state corresponds to the number of holes 70B generated in the quantum dots 60B included in the quantum dot group 63B.

When the bias voltage exceeds the threshold voltage Vth3, holes 70A held in the cores 61A of some quantum dots 60A included in the photoelectric conversion layer 15 pass through the shells 62A. As the bias voltage increases from the threshold voltage Vth3, the number of holes 70A that pass through the shells 62A increases, and the amount of signal charge accordingly increases.

When the bias voltage reaches a threshold Vth2, the holes 70A can pass through the shells 62A of substantially all the quantum dots 60A included in the photoelectric conversion layer 15, that is, the holes 70A can essentially freely move. In other words, the threshold voltage Vth2 corresponds to the threshold voltage for the quantum dot group 63A. After the bias voltage exceeds the threshold voltage Vth2, the amount of signal charge is saturated. An amount P1+P2 of signal charge in a saturated state corresponds to the sum of the number of holes 70B generated in the quantum dots 60B included in the quantum dot group 63B and the number of holes 70A generated in the quantum dots 60A included in the quantum dot group 63A. By subtracting the amount P2 of signal charge from the amount P1+P2 of signal charge, therefore, the number of holes 70A generated in the quantum dots 60A included in the quantum dot group 63A can be obtained.

In the present embodiment, signal charge is read in two stages by adjusting the potential difference between the pixel electrode 11 and the counter electrode 12. More specifically, after signal charge corresponding to the amount P2 of signal charge is output to the charge accumulation node 41, the charge accumulation node 41 is reset. Signal charge corresponding to the amount P1 of signal charge is then output to the charge accumulation node 41. The signal charge held in the quantum dot group 63B and the signal charge held in the quantum dot group 63A can thus be separately read. The potential difference between the pixel electrode 11 and the counter electrode 12 is adjusted by changing the voltage applied by the voltage supply circuit 32 to the counter electrode 12.

### 4. Driving Method

Next, a method for driving the imaging device 100 according to the present embodiment will be described. Although a case where the pixel electrode 11 collects holes as signal charge will be described hereinafter, it is obvious to those skilled in the art that the same operation can be performed to collect electrons by changing polarity as necessary.

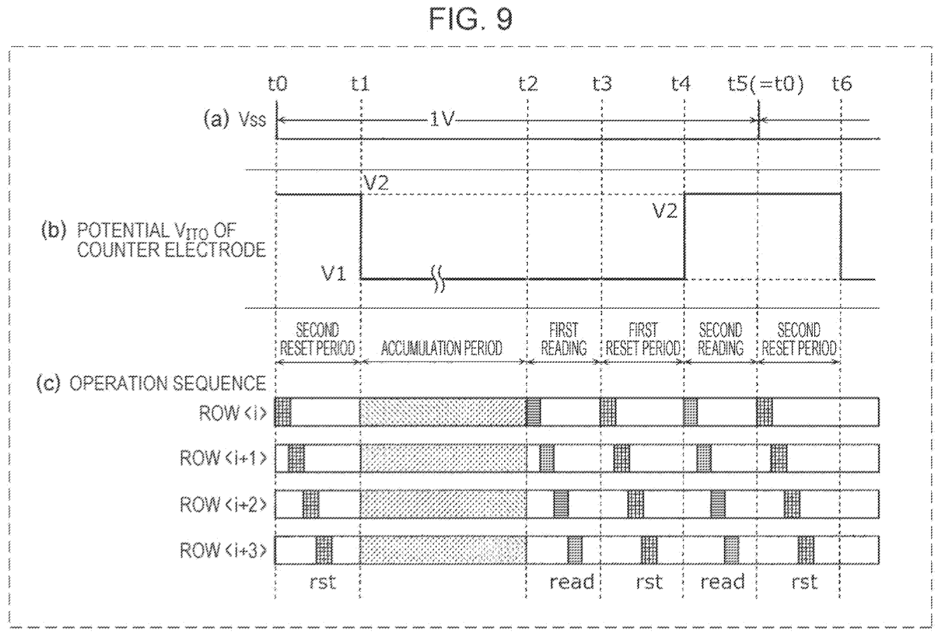

FIG. 9 is a timing chart illustrating the method for driving the imaging device 100 according to the present embodiment. More specifically, portion (a) of FIG. 9 illustrates rising and falling timings of a vertical synchronization signal V_{SS}. Portion (b) of FIG. 9 illustrates an example of temporal changes in a potential V_{ITO} applied by the voltage supply circuit 32 to the counter electrode 12 via the bias control line 42. Portion (c) of FIG. 9 schematically illustrates reset and exposure timings in each of the rows of the pixel array PA.

An example of an operation performed by the imaging device 100 will be described hereinafter with reference to FIGS. 1, 2, 7, 8, and 9. An example of an operation in a case where the number of rows of pixels included in the pixel array PA is a total of four, namely rows <i> to <i+3>, will be described for the sake of simplicity.

As illustrated in portion (c) of FIG. 9, in the imaging device 100 according to the present embodiment, initialization of the pixel array PA and exposure of the pixel array PA, that is, accumulation of charge, resetting of the charge accumulation node 41 of each of the pixels 10 included in the pixel array PA, and reading of pixel signals after the resetting are performed. The initialization of the pixel array PA is essentially the same as the resetting of the charge accumulation nodes 41.

In portion (c) of FIG. 9, rectangular areas named “read” schematically indicate reading periods of signals. Rectangular areas named “rst” schematically indicate reset periods of signals. The reading periods can each include a reset period, in which the potential of the charge accumulation nodes 41 of the pixels 10 is reset.

In the resetting of the pixels 10 in the row <i>, the vertical scanning circuit 36 controls the potential of the address control line 46 in the row <i> in such a way as to turn on the address transistors 26 whose gates are connected to the address control line 46. Furthermore, the vertical scanning circuit 36 controls the potential of the reset control line 48 in the row <i> in such a way as to turn on the reset transistors 28 whose gates are connected to the reset control line 48. As a result, the charge accumulation nodes 41 and the reset voltage lines 44 are electrically connected to each other, and the reset voltage Vr is supplied to the charge accumulation nodes 41. That is, the potential of the gate electrodes 24g of the signal detection transistors 24 and the pixel electrodes 11 of the photoelectric conversion units 13 are reset to the reset voltage Vr. Pixel signals after the resetting are then read from the pixels 10 in the row <i> via the vertical signal lines 47. The pixel signals obtained at this time correspond to the reset voltage Vr. After the pixel signals are read, the reset transistors 28 and the address transistors 26 are turned off.

As schematically illustrated in portion (c) of FIG. 9, the pixels 10 in the rows <i> to <i+3> are sequentially reset in units of rows in this example. As illustrated in portion (b) of FIG. 9, the voltage supply circuit 32 applies control voltage to the counter electrode 12 in a vertical period 1V, which is a period from a beginning of obtaining of an image to an end of the resetting and the reading of pixel signals in all the rows of the pixel array PA, such that the potential difference between the pixel electrode 11 and the counter electrode 12 switches between V1 and V2 so that the tunneling effect is controlled.

Although FIG. 9 illustrates only the voltage applied to the counter electrode 12 for the sake of simplicity, a tunneling effect of holes may be controlled, instead, by controlling the potential of the pixel electrode 11, that is, the reset voltage Vr, in first and second reset periods illustrated in FIG. 9. Alternatively, the tunneling effect may be controlled by appropriately changing a combination of the potential V_{ITO} of the counter electrode 12 and the reset voltage Vr.

A specific operation sequence of the imaging device 100 is as follows.

### Step S0: Initialization (Time t0 to Time t1)

First, signal charge in all the quantum dots included in the photoelectric conversion layers 15 and the charge accumulation nodes 41 is eliminated. That is, from a time t0 to a time t1, all the quantum dots included in the photoelectric conversion layers 15 and the charge accumulation regions are reset.

As illustrated in FIG. 9, for example, resetting of the pixels in the row <i> starts on the basis of the vertical synchronization signal Vss (time t0). More specifically, the bias voltage between each counter electrode 12 and the corresponding pixel electrode 11 is set to a value larger than or equal to the threshold voltage Vth2 for the heterojunction barriers formed by the shells 62A of the quantum dots 60A such that the potential of the counter electrode 12 becomes higher than that of the pixel electrode 11. As the bias voltage is applied between the counter electrode 12 and the pixel electrode 11, an internal field is caused in the photoelectric conversion layer 15 and applied to the quantum dots. For example, the potential V_{ITO} of the counter electrode 12 is set to V2 so that the potential difference between the pixel electrode 11 and the counter electrode 12 becomes the second potential difference, at which the holes 70A can pass through the shells 62A due to a tunneling effect. Charge generated in the quantum dots 60A and 60B is discharged to the pixel electrode 11 or the counter electrode 12, and the photoelectric conversion layer 15 no longer has signal charge, that is, the photoelectric conversion layer 15 enters an initial state. After all the quantum dots included in the photoelectric conversion layers 15 and the charge accumulation regions are reset, initial values of the potential of the charge accumulation regions may be measured.

It is assumed here that the potential of the pixel electrodes 11 is 0 V, that is, the potential V_{ITO} and the bias voltage are the same, for the sake of simplicity. In other words, the potential V_{ITO} of the counter electrode 12 is equal to the bias voltage applied to the counter electrode 12 and the potential difference between the counter electrode 12 and the pixel electrode 11. More specifically, the potential V2 corresponds to the bias voltage V2 and higher than or equal to the threshold voltage Vth2 as illustrated in FIG. 8. The same holds in the following description.

### Step S1: Exposure (Time t1 to Time t2)

Next, the potential V1, at which the quantum dots 60A and 60B can perform photoelectric conversion, is applied to the counter electrode 12 to start the charge accumulation period (from the time t1 to a time t2). Light is radiated onto the imaging device 100 in this state. At this time, signal charge is generated in the cores 61A of the quantum dots 60A and/or the cores 61B of the quantum dots 60B. A step of generating signal charge in the quantum dots through radiation of light will be referred to as “exposure”. The amount of signal charge generated in each quantum dot depends on the spectrum of the light radiated and the spectral sensitivity characteristics of the quantum dot.

The larger the amount of light, the more the quantum dots that generate a hole and an electron. When the amount of light is small, only some quantum dots included in the photoelectric conversion layer 15 generate a hole and an electron. A probability that each quantum dot generates a hole and an electron depends on the absorption spectrum of the quantum dot.

As illustrated in FIG. 7, for example, the holes 70A and the electrons 71A are generated in the cores 61A of the quantum dots 60A. The holes 70A are held by the cores 61A, and the electrons 71A move to the shells 62A. Similarly, the holes 70B and the electrons 71B are generated in the cores 61B of the quantum dots 603. The holes 70B are held in the cores 61B, and the electrons 71B move to the shells 62B.

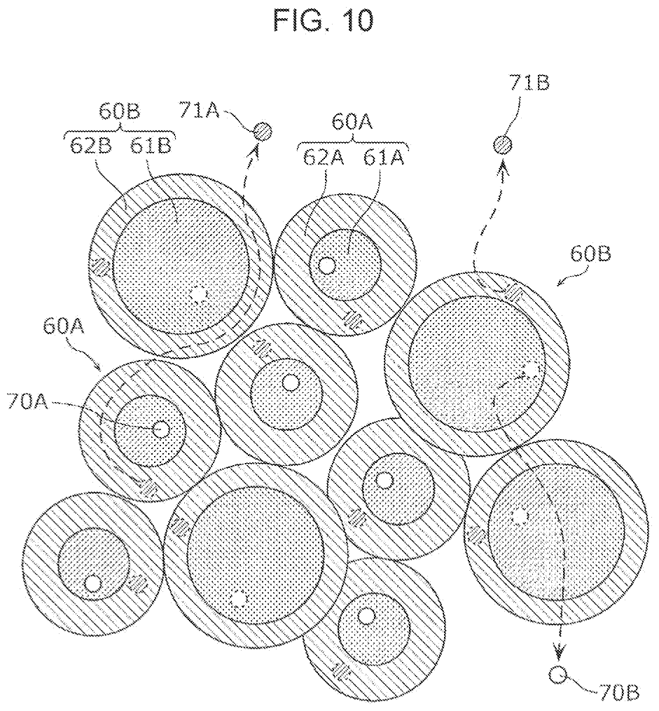

Since the potential of the counter electrode 12 is higher than that of the pixel electrode 11, movement of charge illustrated in FIG. 10 occurs, More specifically, in the photoelectric conversion layer 15, the quantum dots are in close proximity to one another. The electrons 71A generated in the quantum dots 60A and the electrons 71B generated in the quantum dots 60B, therefore, move along the shells 62A of adjacent quantum dots 60A or the shells 62B of adjacent quantum dots 60B. The electrons 71A and the electrons 71B are collected by the counter electrode 12, which has a higher potential than the pixel electrode 11.

The holes 70A generated in the quantum dots 60A and the holes 70B generated in the quantum dots 60B, on the other hand, keep being confined in the cores 61A and the cores 61B, respectively, when the bias voltage is lower than the threshold voltage Vth0. In the present embodiment, the potential difference between the counter electrode 12 and the pixel electrode 11 during the exposure is the potential difference V1, at which the holes 70B can pass through the shells 62B of the quantum dots 60B, that is, larger than or equal to the threshold voltage Vth1 illustrated in FIG. 8. The holes 70B, therefore, can essentially freely move. As illustrated in FIG. 10, the holes 70B are collected by the pixel electrode 11, whose potential is lower than that of the counter electrode 12.

### Step S2: First Charge Reading (Time t2 to Time t3)

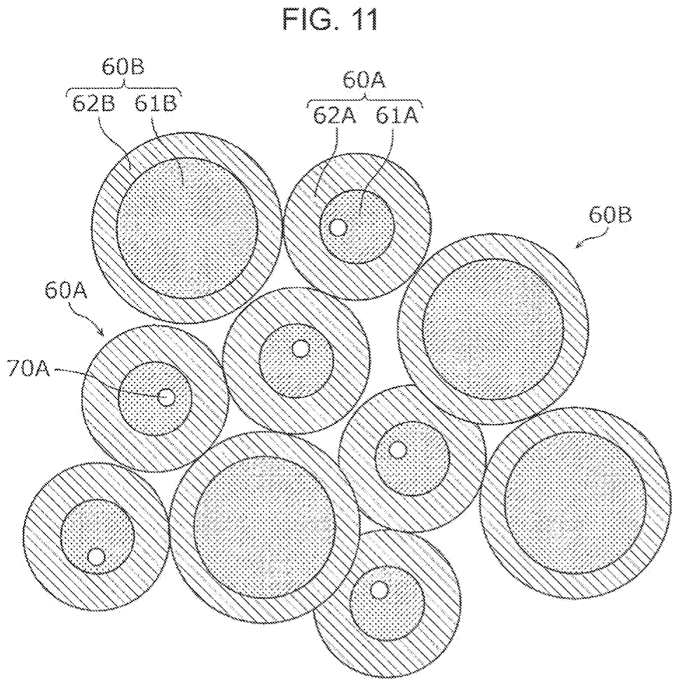

After the exposure is completed, only the holes 70A generated in the cores 61A of the quantum dots 60A included in the quantum dot group 63A are held in the cores 61A in the photoelectric conversion layer 15 as illustrated in FIG. 11. The holes 70B generated in the cores 61B of the quantum dots 60B included in the quantum dot group 63B are accumulated in the charge accumulation node 41. The signal detection circuit 14, therefore, measures the amount of charge accumulated in the charge accumulation node 41. The amount of charge accumulated in the charge accumulation node 41 is equal to the amount P2 of signal charge generated in the quantum dot group 63B.

More specifically, as illustrated in portion (c) of FIG. 9, charge is sequentially read from the row <i> through a rolling operation. Time taken for the rolling operation to complete can be reduced by using a chip stacking technique by which a reading circuit and a photoelectric conversion unit are stacked on each other or separately providing a memory in each of the pixels 10.

### Step S3: First Charge Resetting (Time t3 to Time t4)

After the first charge reading is completed, the signal charge accumulated in the charge accumulation node 41 is eliminated. As illustrated in portion (b) of FIG. 9, the potential V_{ITO} of the counter electrode 12 is kept at V1 from the time t2 to the time t4, during which the first charge reading and the first resetting are performed. That is, as illustrated in FIG. 11, the holes 70A generated in the cores 61A of the quantum dots 60A do not pass through the shells 62A and are held in the cores 61A.

### Step S4: Charge Transfer (Time t4)

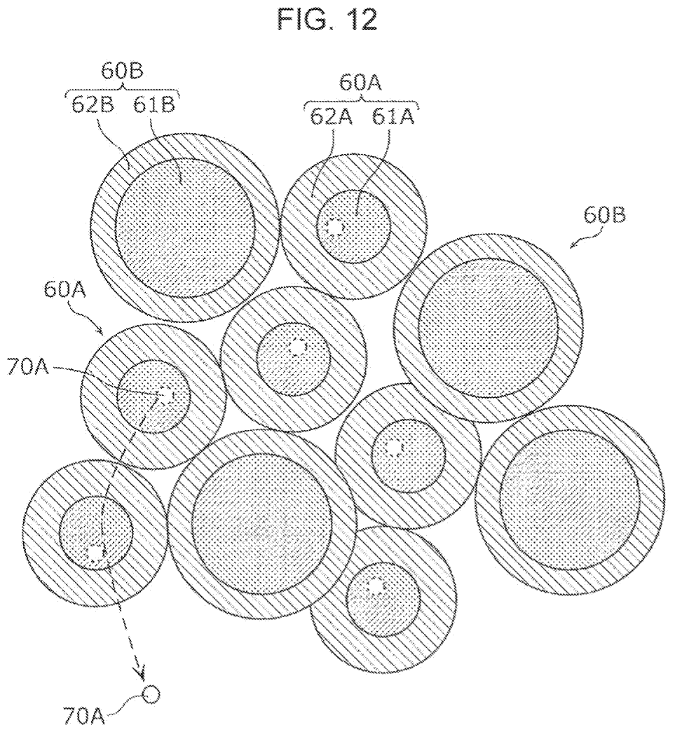

After the first charge resetting is completed, the bias voltage between the counter electrode 12 and the pixel electrode 11 is set to a value larger than or equal to the threshold voltage Vth2. More specifically, as illustrated in portion (b) of FIG. 9, the potential V_{ITO} of the counter electrode 12 is set to V2 at the time t4 so that the potential difference between the counter electrode 12 and the pixel electrode 11 becomes the second potential difference. By applying the bias voltage, the holes 70A accumulated in the cores 61A of the quantum dots 60A pass through the shells 62A due to a tunneling effect, are collected by the pixel electrode 11, and are accumulated in the charge accumulation node 41 as illustrated in FIG. 12.

### Step S5: Second Charge Reading (Time t4 to Time t5)

When the charge transfer is completed, the holes 70A generated in the cores 61A of the quantum dots 60A included in the quantum dot group 63A have been accumulated in the charge accumulation node 41. The signal detection circuit 14, therefore, measures the amount of charge accumulated in the charge accumulation node 41. The amount of charge accumulated in the charge accumulation node 41 is equal to the amount P1 of signal charge generated in the quantum dot group 63A. More specifically, as illustrated in portion (c) of FIG. 9, charge is sequentially read from the row <i> through a rolling operation. The reading operation is the same as in the first charge reading (step S2).

### Step S6: Second Charge Resetting (Time t5 to Time t6)

After the second charge reading is completed, the signal charge accumulated in the charge accumulation nodes 41 is eliminated. As a result, the photoelectric conversion layers 15 and the charge accumulation nodes 41 are reset, and the pixel array PA are initialized. That is, the state at the time t1 is established again at a time t6. A moving image can be obtained by repeating steps S1 to S6.

Signal charge generated in the quantum dot groups 63A and 63B can thus be separately read using a difference between the threshold voltages for the quantum dot groups 63A and 63B. Since the resonant wavelengths of the quantum dot groups 63A and 63B are different from each other as illustrated in FIG. 6, an image can be captured with two different spectra in each pixel.

Imaging results based on two different spectra can thus be read from each pixel electrode 11 in the present embodiment, and wiring proportionate to the number of spectra need not be provided. In step S2 and later, the radiation of light onto the imaging device 100 may be restricted using a mechanism such as a mechanical shutter, instead, in order to avoid unnecessary photoelectric conversion.

In addition, since the voltage applied to the counter electrode 12 is kept at V1 or higher after the exposure period ends in the present embodiment, a bias voltage higher than or equal to the threshold voltage Vth1 is applied to the photoelectric conversion layer 15 after the accumulation of signal charge in the charge accumulation node 41 ends. When the bias voltage higher than or equal to the threshold voltage Vth1 is applied to the photoelectric conversion layer 15, signal charge already accumulated in the charge accumulation node 41 can be prevented from moving to the counter electrode 12 via the photoelectric conversion layer 15. In other words, by applying a bias voltage higher than or equal to a threshold bias voltage for the photoelectric conversion layer 15, signal charge accumulated in the exposure period can be kept in the charge accumulation node 41. That is, occurrence of negative parasitic sensitivity due to a loss of signal charge from the charge accumulation node 41 can be suppressed,

In the driving method illustrated in FIG. 9, an accumulation period does not perfectly match between the quantum dot groups 63A and 63B. More specifically, an accumulation period of the quantum dot group 63B is essentially from the time t1 to an end of a first reading period. An accumulation period of the quantum dot group 63A is from the time t1 to an end of a second reading period. This difference between the accumulation periods is substantially negligible when the reading is performed with a high-speed rolling operation.

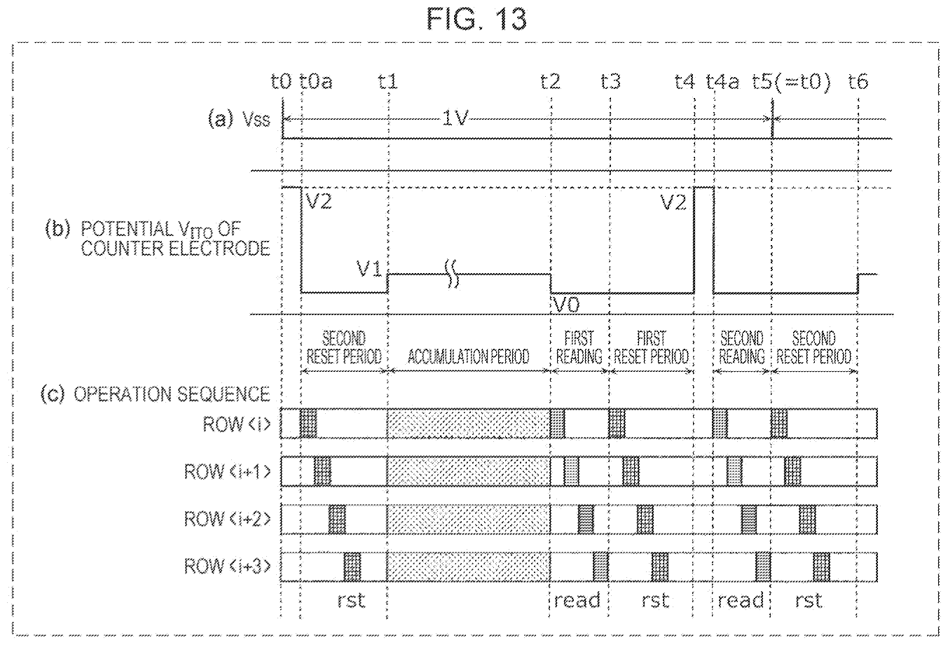

Alternatively, the imaging device 100 may be driven on the basis of an operation illustrated in FIG. 13. FIG. 13 is a timing chart illustrating another example of the method for driving the imaging device 100 according to the present embodiment. In the example illustrated in FIG. 13, after charge is transferred to the charge accumulation node 41 from the quantum dot groups, the sensitivity of the quantum dot groups becomes zero, that is, the quantum dot groups enter a global shutter state. The reading and resetting of the charge transferred to the charge accumulation node 41 from the quantum dot groups are performed in the global shutter state. In the global shutter state, signal charge is not newly generated in the quantum dot groups.

From the time t2 to the time t4, for example, the potential V_{ITO} of the counter electrode 12 is set to a potential V0, at which the sensitivity of the quantum dot groups becomes zero. The potential V0 is lower than the threshold voltage Vth0 illustrated in FIG. 8. At the potential V0, for example, the potential difference between the counter electrode 12 and the pixel electrode 11 becomes zero. As a result, accumulation of charge during the reading periods and the reset periods due to the rolling operation can be prevented.

In the example illustrated in FIG. 13, the global shutter state is established from a time t0a to the time t1, from the time t2 to the time t4, and from a time t4a to the time t6. A period for transferring signal charge to the charge accumulation node 41 from the quantum dot groups is provided immediately before the time t0a and the time t4a.

A period from the time t0 to the time t0a, for example, is a period for transferring charge remaining in the quantum dot groups 63A and 63B for the initialization. In the period from the time t0 to the time t0a, the potential V_{ITO} of the counter electrode 12 is V2 as illustrated in portion (b) of FIG. 13. As a result, the holes 70A generated in the quantum dot group 63A pass through the shells 62A and are transferred to the charge accumulation node 41, and the holes 70B generated in the quantum dot group 63B pass through the shells 62B and are transferred to the charge accumulation node 41. That is, the entirety of signal charge in the photoelectric conversion layer 15 is transferred to the charge accumulation node 41.

A period from the time t4 to the time t4a is a period for transferring the holes 70A held in the cores 61A. As illustrated in portion (b) of FIG. 13, the potential V_{ITO} of the counter electrode 12 is V2. As a result, the holes 70A generated in the cores 61A pass through the shells 62A and are transferred to the charge accumulation node 41. That is, signal charge in the quantum dot group 63A is transferred to the charge accumulation node 41.

Signal charge to be read is thus transferred to the charge accumulation node 41 immediately before the global shutter state is established. The reading and the resetting are then performed in the global shutter state. The period from the time t0 to the time t0a and the period from the time t4 to the time t4a, in which charge is transferred, are shorter than a period for which the global shutter state remains established. An effect produced by the difference between essential lengths of the exposure periods of the quantum dot groups, therefore, can be reduced.

Although signal charge in the quantum dot groups is sequentially read in the present embodiment, signal charge in the quantum dot groups may be read at once. In FIGS. 9 and 13, for example, if the first reset period from the time t3 to the time t4 is omitted, the total amount of signal charge generated in the quantum dot groups 63A and 63B can be read in a period from the time t4 to the time t6. The amount of signal charge in each of the quantum dot groups may be calculated in an analog domain or a digital domain using differential circuits provided outside the pixels 10. As a result, the reading periods can be reduced.

In the reset periods, a simultaneous reset operation, in which all pixels are simultaneously reset, may be performed instead of the rolling operation illustrated in FIGS. 9 and 13. In doing so, the reset periods can be reduced. Since signal charge in the quantum dot groups is read, the number of times of resetting is larger than in the case of a common single-layer sensor or a silicon sensor. An effect of reducing time produced by the simultaneous reset operation is especially great.

A beginning and an end of the exposure period are thus controlled by the voltage V_{ITO} applied to the counter electrode 12 in the present embodiment. That is, according to the present embodiment, a function of a global shutter or a function of globally changing sensitivity and a function of transferring charge in the same direction as light vertically incident on the imaging device 100 can be achieved without providing a transfer transistor or the like for each of the pixels 10. In the present embodiment, signal charge is not transferred using a transfer transistor. Since charge can be transferred and sensitivity can be changed by controlling the voltage V_{ITO}, operation can be performed at higher speed. In addition, since a transfer transistor need not be separately provided for each of the pixels 10, the pixels 10 can be reduced in size.

### Second Embodiment

Next, a second embodiment will be described. The second embodiment is different from the first embodiment in that a photoelectric conversion layer includes hole confining type-II quantum dots and electron confining type-II quantum dots. Differences from the first embodiment will be mainly described hereinafter, and description of common features is omitted or simplified.

### 1. Structure

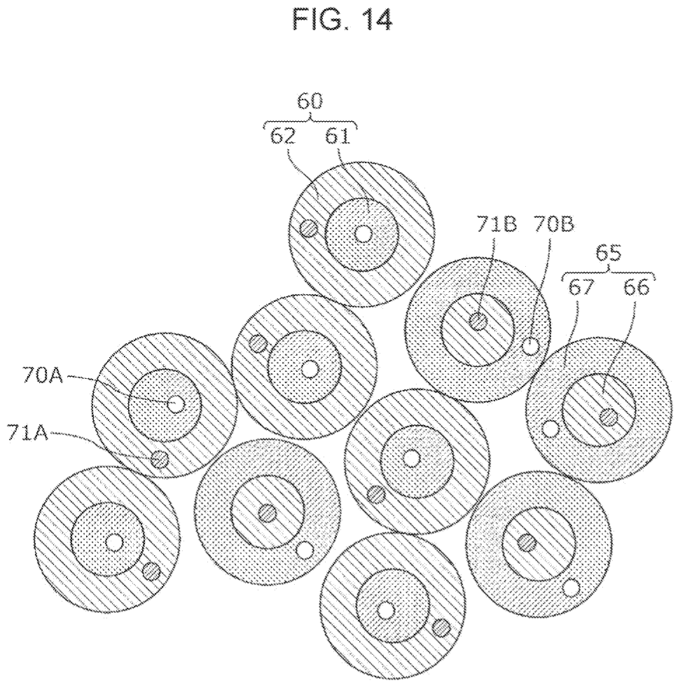

FIG. 14 is a schematic diagram illustrating the structure of a photoelectric conversion layer 15 in an imaging device and charge generated during exposure according to the present embodiment. As illustrated in FIG. 14, the photoelectric conversion layer 15 includes quantum dots 60 and quantum dots 65.

Each of the quantum dots 60 is the hole confining type-II quantum dot 60 illustrated in FIG. 3. The quantum dots 60 form a first quantum dot group.

Each of the quantum dots 65 is the electron confining type-II quantum dot 65 illustrated in FIG. 4. The quantum dots 65 form a second quantum dot group.

In the present embodiment, an average of resonant wavelengths in the first quantum dot group and an average of resonant wavelengths in the second quantum dot group are different from each other. For example, an absorption spectrum of the first quantum dot group is the same as that of the quantum dot group 63A illustrated in FIG. 6. For example, an absorption spectrum of the second quantum dot group is the same as that of the quantum dot group 63B illustrated in FIG. 6.

### 2. Driving Method

Next, a method for driving the imaging device according to the present embodiment will be described. Although a case where the pixel electrode 11 collects holes as signal charge will be described, it is obvious to those skilled in the art that the same operation can be performed to collect electrons by changing polarity as necessary.

A specific operation sequence of the imaging device is the same as that of the imaging device 100 according to the first embodiment illustrated in FIG. 9. Behavior of holes and electrons in the photoelectric conversion layer 15 will be mainly described hereinafter.

### Step S0: Initialization (Time t0 to Time t1)

First, signal charge in all the quantum dots included in the photoelectric conversion layers 15 and the charge accumulation nodes 41 is eliminated. That is, from the time t0 to the time t1, all the quantum dots included in the photoelectric conversion layers 15 and the charge accumulation regions are reset.

As illustrated in FIG. 9, for example, resetting of the pixels in the row <i> starts on the basis of the vertical synchronization signal Vss (time t0). More specifically, the bias voltage between each counter electrode 12 and the corresponding pixel electrode 11 is set to a value larger than or equal to the threshold voltage Vth2 for the heterojunction barriers formed by the shells 62 of the quantum dots 60 and a threshold voltage for heterojunction barriers formed by the shells 67 of the quantum dots 65 such that the potential of the counter electrode 12 becomes higher than that of the pixel electrode 11. As the bias voltage is applied between the counter electrode 12 and the pixel electrode 11, an internal field is caused in the photoelectric conversion layer 15 and applied to the quantum dots. For example, the potential V_{ITO} of the counter electrode 12 is set to V2 so that the potential difference between the pixel electrode 11 and the counter electrode 12 becomes the second potential difference, at which the holes 70A can pass through the shells 62 due to a tunneling effect and the electrons 71B can pass through the shells 67 due to a tunneling effect. Charge generated in the quantum dots 60 and 65 is discharged to the pixel electrode 11 or the counter electrode 12, and the photoelectric conversion layer 15 no longer has signal charge, that is, the photoelectric conversion layer 15 enters an initial state. After all the quantum dots included in the photoelectric conversion layers 15 and the charge accumulation regions are reset, initial values of the potential of the charge accumulation regions may be measured.

### Step S1: Exposure (Time t1 to Time t2)

Next, the potential V1, at which the quantum dots 60 and 65 can perform photoelectric conversion, is applied to the counter electrode 12 to start the charge accumulation period (from the time t1 to a time t2). Light is radiated onto the imaging device in this state. At this time, signal charge is generated in the cores 61 of the quantum dots 60 and/or the cores 66 of the quantum dots 65.

As illustrated in FIG. 14, for example, the holes 70A and the electrons 71A are generated in the cores 61 of the quantum dots 60. The holes 70A are held by the cores 61, and the electrons 71A move to the shells 62. Similarly, the holes 70B and the electrons 71B are generated in the cores 66 of the quantum dots 65. The electrons 71B are held by the cores 66, and the holes 70B move to the shells 67.

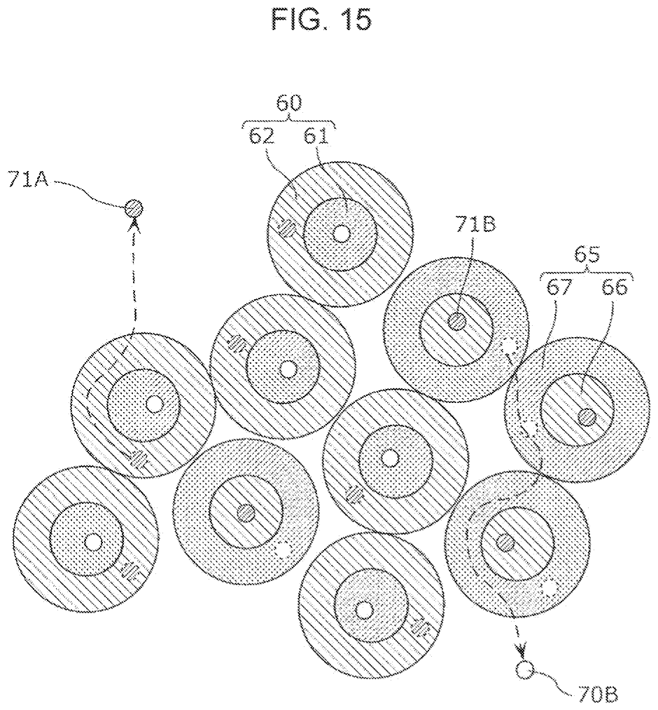

Since the potential of the counter electrode 12 is higher than that of the pixel electrode 11, movement of charge illustrated in FIG. 15 occurs. More specifically, the electrons 71A generated in the quantum dots 60 and the holes 70B generated in the quantum dots 65 move along the shells 62 of adjacent quantum dots 60 or the shells 67 of adjacent quantum dots 65. The electrons 71A are collected by the counter electrode 12, which has a higher potential than the pixel electrode 11. The holes 70B are collected by the pixel electrode 11, which has a lower potential than the counter electrode 12. The holes 70B collected by the pixel electrode 11 are accumulated in the charge accumulation node 41 as signal charge.

In the present embodiment, the bias voltage during the exposure is a voltage V1, which is lower than the threshold voltage Vth2 for the heterojunction barriers formed by the shells 62 of the quantum dots 60 and the threshold voltage for the heterojunction barriers formed by the shells 67 of the quantum dots 65. The holes 70A generated in the quantum dots 60 and the electrons 71B generated in the quantum dots 65, therefore, keep being confined in the cores 61 and the cores 66, respectively, since a tunneling effect is not produced if the bias voltage is lower than the threshold voltages.

### Step S2: First Charge Reading (Time t2 to Time t3)

When the exposure is completed, the holes 70B generated in the cores 66 of the quantum dots 65 included in the second quantum dot group have been accumulated in the charge accumulation node 41. The signal detection circuit 14, therefore, measures the amount of charge accumulated in the charge accumulation node 41. The amount of charge accumulated in the charge accumulation node 41 is equal to the amount P2 of signal charge generated in the second quantum dot group.

### Step S3: First Charge Resetting (Time t3 to Time t4)

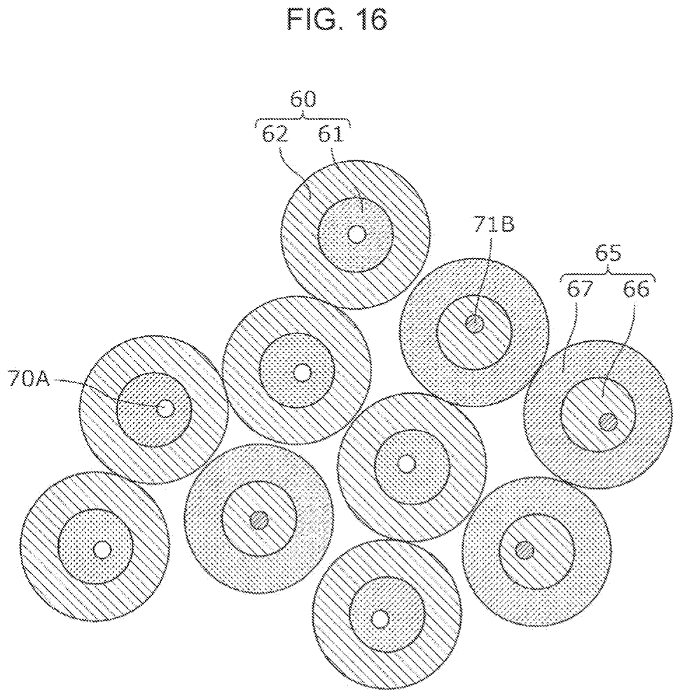

After the first charge reading is completed, the signal charge accumulated in the charge accumulation node 41 is eliminated. As illustrated in portion (b) of FIG. 9, the potential V_{ITO} of the counter electrode 12 is kept at V1 from the time t2 to the time t4, during which the first charge reading and the first resetting are performed. That is, as illustrated in FIG. 16, the holes 70A generated in the cores 61 of the quantum dots 60 do not pass through the shells 62 and are held in the cores 61. Similarly, the electrons 71B generated in the cores 66 of the quantum dots 65 do not pass through the shells 67 and are held in the cores 66, Because the electrons 71B are not used as signal charge, the voltage V1 applied to the counter electrode 12 in steps S1 to S3 may be a voltage at which the electrons 71B pass through the shells 67, instead. When the first charge reading is completed, the electrons 713 may be collected in the counter electrode 12 and only the holes 70A may be held in the cores 61 of the quantum dots 60, instead.

### Step S4: Charge Transfer (Time t4)

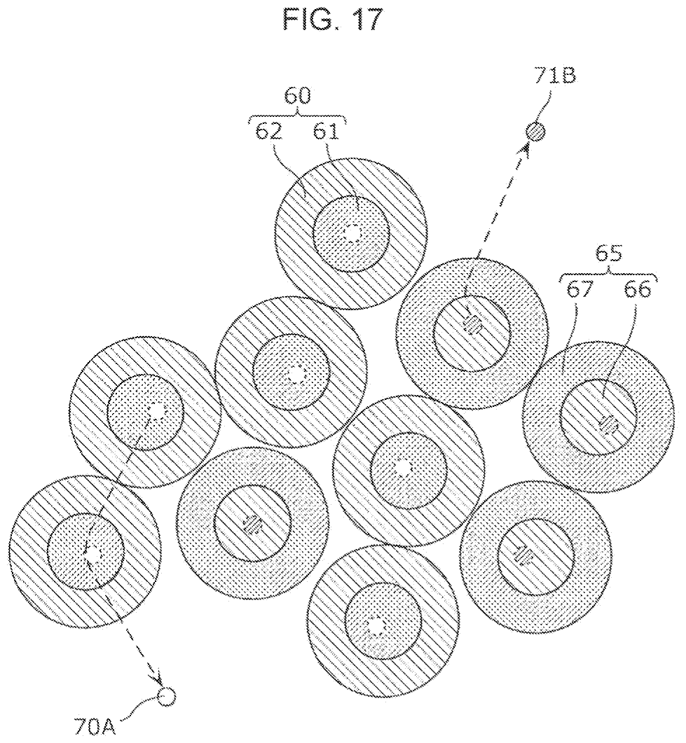

After the first charge resetting is completed, the bias voltage between the counter electrode 12 and the pixel electrode 11 is set to a value larger than or equal to the threshold voltage Vth2. More specifically, as illustrated in portion (b) of FIG. 9, the potential V_{ITO} of the counter electrode 12 is set to V2 at the time t4 so that the potential difference between the counter electrode 12 and the pixel electrode 11 becomes the second potential difference. By applying the bias voltage, the holes 70A accumulated in the cores 61 of the quantum dots 60 pass through the shells 62 due to a tunneling effect, are collected by the pixel electrode 11, and are accumulated in the charge accumulation node 41 as illustrated in FIG. 17. The electrons 71B accumulated in the cores 66 of the quantum dots 65, too, pass through the shells 67 due to a tunneling effect and are collected by the counter electrode 12.

Step S5: Second Charge Reading (Time t4 to Time t5)

When the charge transfer is completed, the holes 70A generated in the cores 61 of the quantum dots 60 included in the first quantum dot group have been accumulated in the charge accumulation node 41. The signal detection circuit 14, therefore, measures the amount of charge accumulated in the charge accumulation node 41. The amount of charge accumulated in the charge accumulation node 41 is equal to the amount P1 of signal charge generated in the first quantum dot group. A specific reading operation is the same as in the first charge reading (step S2).

### Step S6: Second Charge Resetting (Time t5 to Time t6)

After the second charge reading is completed, the signal charge accumulated in the charge accumulation nodes 41 is eliminated. As a result, the photoelectric conversion layers 15 and the charge accumulation nodes 41 are reset, and the pixel array PA are initialized. That is, the state at the time t1 is established again at a time t6. A moving image can be obtained by repeating steps S1 to S6.

After the second charge reading is completed, the electrons 71B generated in the cores 66 of the quantum dots 65 may keep being held in the cores 66. In this case, the potential difference between the counter electrode 12 and the pixel electrode 11 may be increased so that the electrons 71B can easily pass through the sheds 67 due to a tunneling effect.

As described above, in the imaging device according to the present embodiment, polarities of charge confined in the first and second quantum dot groups included in the photoelectric conversion layer 15 are different from each other. As a result, imaging results based on two different spectra can be read from each pixel electrode 11 as in the first embodiment, and wiring proportionate to the number of spectra need not be provided. Consequently, a high-resolution, high-sensitivity imaging device can be achieved.

### Third Embodiment

Next, a third embodiment will be described. The third embodiment is different from the first embodiment in that a photoelectric conversion unit includes three quantum dot groups. Differences from the first embodiment will be mainly described hereinafter, and description of common features is omitted or simplified.

### 1. Structure

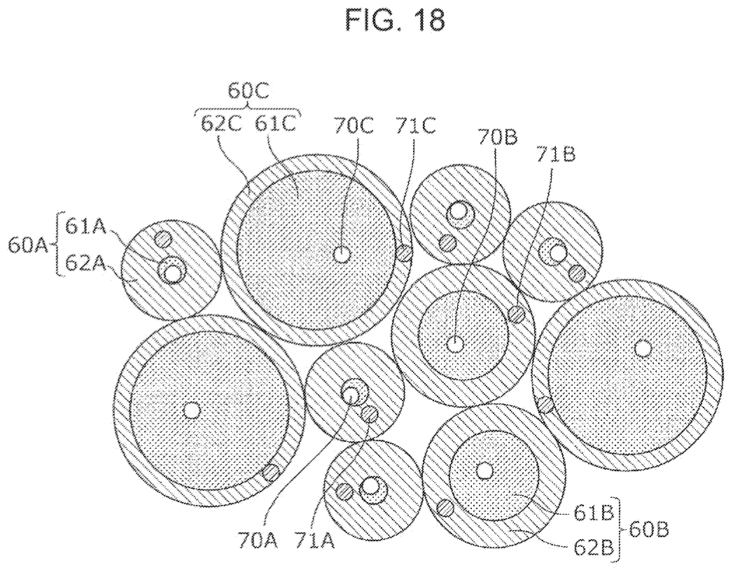

FIG. 18 is a schematic diagram illustrating the structure of a photoelectric conversion layer 15 in an imaging device and charge generated during exposure according to the present embodiment. As illustrated in FIG. 18, the photoelectric conversion layer 15 includes quantum dots 60A, 60B, and 60C.

The quantum dots 60A, 60B, and 60C are type-II quantum dots that confine charge of the same polarity. More specifically, the quantum dots 60A, 60B, and 60C are hole confining type-II quantum dots. Alternatively, the quantum dots 60A, 60B, and 60C may be electron confining type-II quantum dots.

The quantum dots 60A each include a core 61A and a shell 62A. The quantum dots 60A form a first quantum dot group.

The quantum dots 60B each include a core 61B and a shell 62B. The quantum dots 60B form a second quantum dot group.

The quantum dots 60C each include a core 61C and a shell 62C. The quantum dots 60C form a third quantum dot group.

For example, the cores 61B are larger than the cores 61A but smaller than the cores 61C. That is, since the cores 61A are the smallest, a resonant wavelength thereof is shorter than those of the cores 61B and the cores 61C. Since the cores 61C are the largest, the resonant wavelength thereof is longer than those of the cores 61A and the cores 61B.

An average of resonant wavelengths in the first quantum dot group, an average of resonant wavelengths in the second quantum dot group, and an average of resonant wavelengths in the third quantum dot group are different from one another. For example, an absorption spectrum of the first quantum dot group has an absorption peak in blue light. An absorption spectrum of the second quantum dot group has an absorption peak in green light. An absorption spectrum of the third quantum dot group has an absorption peak in red light. As a result, each pixel electrode 11 can separately read red, green, and blue (RGB) components. The number of quantum dot groups included in the photoelectric conversion layer 15 may be four or more, instead.

In addition, for example, the shells 62B are thinner than the shells 62A but thicker than the shells 62C. That is, since the shells 62A are the thickest, heterojunction barriers formed by the shells 62A are the largest. A threshold voltage for charge generated in the cores 61A covered by the shells 62A to pass through the shells 62A due to a tunneling effect, therefore, is the highest. Since the shells 62C are the thinnest, heterojunction barriers formed by the shells 62C are the smallest. A threshold voltage for charge generated in the cores 61C covered by the shells 62C to pass through the shells 62C due to a tunneling effect, therefore, is the lowest.

Threshold voltages for the first to third quantum dot groups are thus different from one another. More specifically, the threshold voltage for the first quantum dot group is the highest, and the threshold voltage for the third quantum dot group is the lowest. Alternatively, averages of thicknesses of the shells in the quantum dot groups may be the same, and the threshold voltages may be made different from one another by using different materials for the cores and the shells and providing differences in the energy level.

### 2. Driving Method

Next, a method for driving the imaging device according to the present embodiment will be described. Although a case where the pixel electrode 11 collects holes as signal charge will be described, it is obvious to those skilled in the art that the same operation can be performed to collect electrons by changing polarity as necessary.

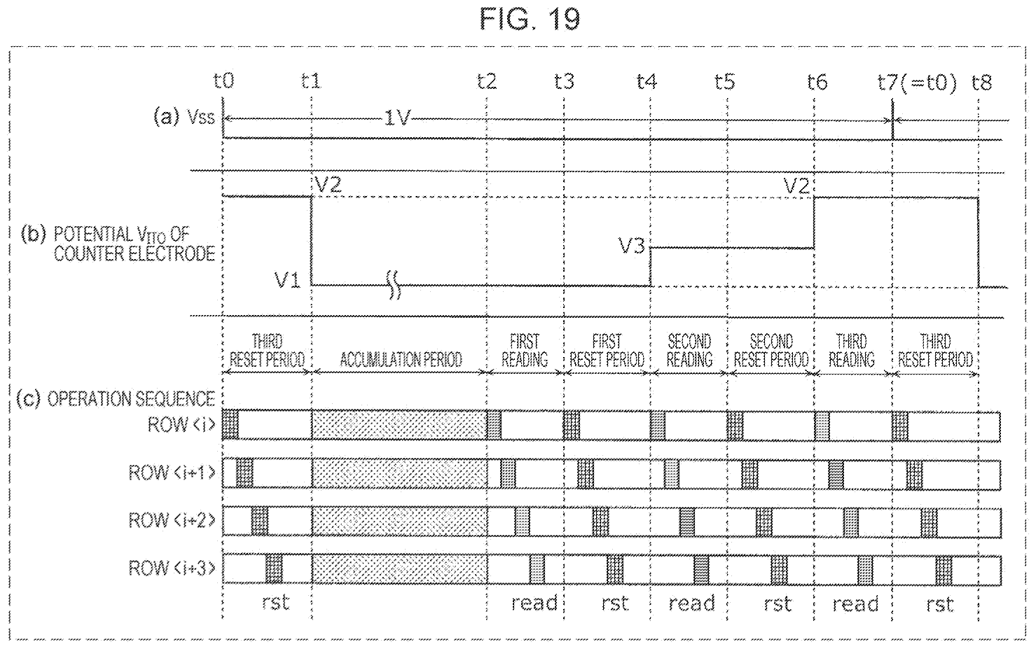

FIG. 19 is a timing chart illustrating the method for driving the imaging device according to the present embodiment. The driving method that will be described hereinafter is substantially the same as that described in the first embodiment and different from the driving method described in the first embodiment in that charge reading and resetting are performed three times each, not twice each. The voltage supply circuit 32 accordingly changes the voltage applied to the counter electrode 12 between three values.

A specific operation sequence of the imaging device is as follows.

### Step S1: Exposure (Time t1 to Time t2)

The potential V1, at which the quantum dots 60A, 60B, and 60C can perform photoelectric conversion, is applied to the counter electrode 12 to start the charge accumulation period (from the time t1 to a time t2). Light is radiated onto the imaging device in this state. At this time, signal charge is generated in at least one of the cores 61A of the quantum dots 60A, the cores 61B of the quantum dots 60B, or the cores 61C of the quantum dots 60C.

As illustrated in FIG. 18, for example, the holes 70A and the electrons 71A are generated in the cores 61A of the quantum dots 60A. The holes 70A are held by the cores 61A, and the electrons 71A move to the shells 62A. Similarly, the holes 70B and the electrons 71B are generated in the cores 61B of the quantum dots 60B. The holes 70B are held by the cores 61B, and the electrons 71B move to the shells 62B. Holes 70C and electrons 71C are generated in the cores 61C of the quantum dots 60C. The holes 70C and the electrons 71C are generated in the cores 61C of the quantum dots 60C. The holes 70C are held by the cores 61C, and the electrons 71C move to the shells 62C.

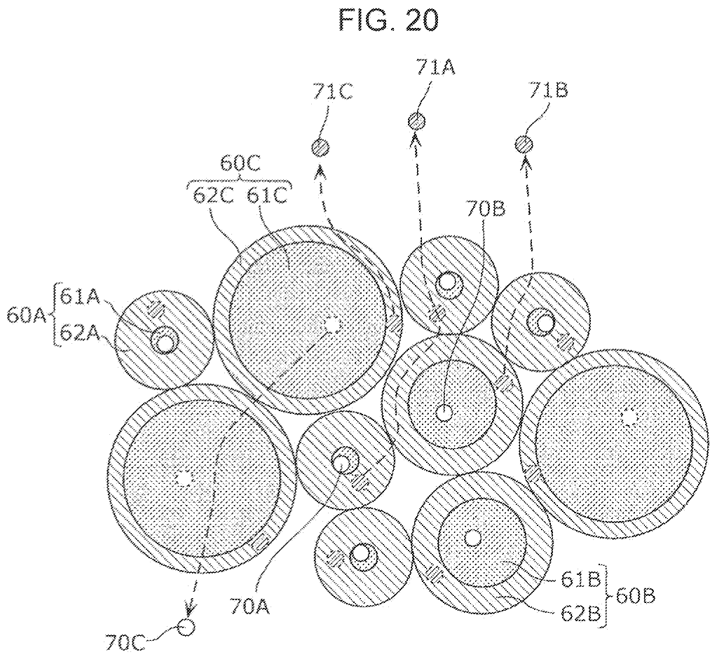

Since the potential of the counter electrode 12 is higher than that of the pixel electrode 11, movement of charge illustrated in FIG. 20 occurs. More specifically, the electrons 71A generated in the quantum dots 60A, the electrons 71B generated in the quantum dots 60B, and the electrons 71C generated in the quantum dots 60C move along the shells 62A of adjacent quantum dots 60A, the shells 62B of adjacent quantum dots 60B, or the shells 62C of adjacent quantum dots 60C. The electrons 71A, 71B, and 71C are collected by the counter electrode 12, which has a higher potential than the pixel electrode 11.

The holes 70A generated in the quantum dots 60A, the holes 70B generated in the quantum dots 60B, and the holes 70C generated in the quantum dots 60C, on the other hand, keep being confined in the cores 61A, the cores 61B, and the cores 61C, respectively, if the bias voltage is lower than the threshold voltage Vth0. In the present embodiment, the potential difference between the counter electrode 12 and the pixel electrode 11 during the exposure is the potential difference V1, at which the holes 70C can pass through the shells 62C of the quantum dots 60C. The holes 70C, therefore, can essentially freely move. As illustrated in FIG. 20, the holes 70C are collected by the pixel electrode 11 whose potential is lower than that of the counter electrode 12.

### Step S2: First Charge Reading (Time t2 to Time t3)

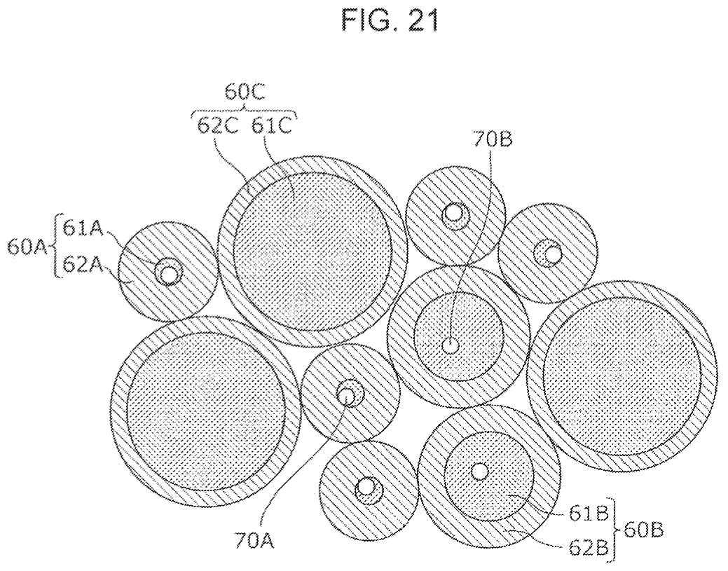

As illustrated in FIG. 21, after the exposure is completed, the holes 70A generated in the cores 61A of the quantum dots 60A included in the first quantum dot group and the holes 70B generated in the cores 61B of the quantum dots 60B included in the second quantum dot group are held in the cores 61A and the cores 61B, respectively, in the photoelectric conversion layer 15. The holes 70C generated in the cores 61C of the quantum dots 60C included in the third quantum dot group are accumulated in the charge accumulation node 41. The signal detection circuit 14, therefore, measures the amount of charge accumulated in the charge accumulation node 41. The amount of charge accumulated in the charge accumulation node 41 is equal to the amount of signal charge generated in the third quantum dot group. More specifically, as illustrated in portion (c) of FIG. 19, charge is sequentially read from the row <i> through a rolling operation.

### Step S3: First Charge Resetting (Time t3 to Time t4)

After the first charge reading is completed, the signal charge accumulated in the charge accumulation node 41 is eliminated. As illustrated in portion (b) of FIG. 19, the potential V_{ITO} of the counter electrode 12 is kept at V1 from the time t2 to the time t4, during which the first charge reading and the first resetting are performed. That is, as illustrated in FIG. 21, the holes 70A generated in the cores 61A of the quantum dots 60A do not pass through the shells 62A and are held in the cores 61A. The holes 70B generated in the cores 61B of the quantum dots 60B do not pass through the shells 62B and are held in the cores 61B.

### Step S4: First Charge Transfer (Time t4)

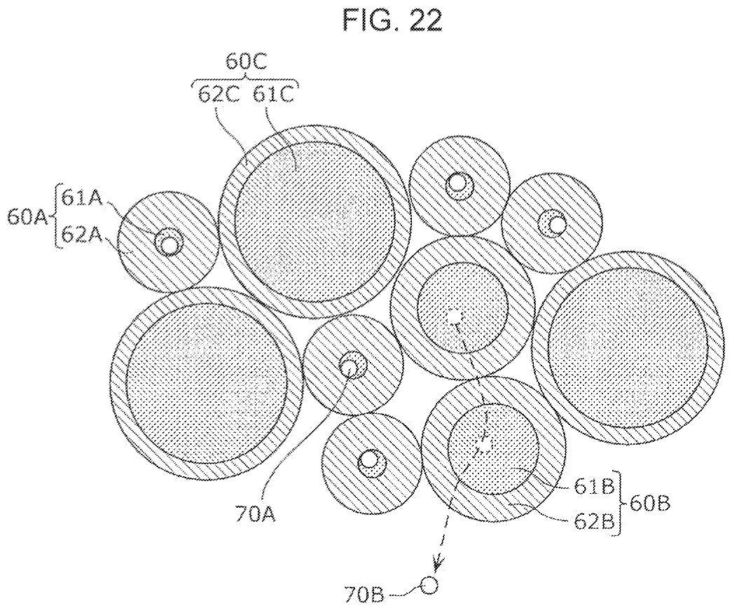

After the first charge resetting is completed, the bias voltage between the counter electrode 12 and the pixel electrode 11 is set to a value larger than or equal to the threshold voltage for the second quantum dot group but smaller than the threshold voltage for the first quantum dot group. More specifically, as illustrated in portion (b) of FIG. 19, the potential V_{ITO} of the counter electrode 12 is set to V3 at the time t4 so that the potential difference between the counter electrode 12 and the pixel electrode 11 becomes a third potential difference. By applying the bias voltage, the holes 70B accumulated in the cores 61B of the quantum dots 60B pass through the shells 62B due to a tunneling effect, are collected by the pixel electrode 11, and are accumulated in the charge accumulation node 41 as illustrated in FIG. 22.

### Step S5: Second Charge Reading (Time t4 to Time t5)

When the charge transfer is completed, the holes 70B generated in the cores 61B of the quantum dots 60B included in the second quantum dot group have been accumulated in the charge accumulation node 41. The signal detection circuit 14, therefore, measures the amount of charge accumulated in the charge accumulation node 41. The amount of charge accumulated in the charge accumulation node 41 is equal to the amount of signal charge generated in the second quantum dot group. More specifically, as illustrated in portion (c) of FIG. 19, charge is sequentially read from the row <i> through a rolling operation. The rolling operation is the same as in the first charge reading (step S2).

### Step S6: Second Charge Resetting (Time t5 to Time t6)

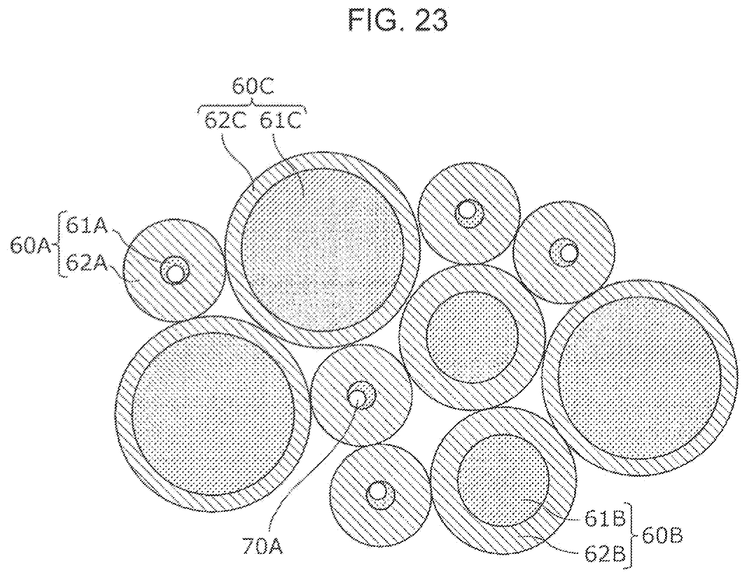

After the second charge reading is completed, the signal charge accumulated in the charge accumulation nodes 41 is eliminated. As illustrated in portion (b) of FIG. 19, the potential V_{ITO} of the counter electrode 12 is kept at V3 from the time t4 to the time t6, during which the first charge transfer, the second charge reading, and the second resetting are performed. As illustrated in FIG. 23, therefore, the holes 70A generated in the cores 61A of the quantum dots 60A included in the first quantum dot group do not pass through the shells 62A and are held in the cores 61A.

### Step S7: Second Charge Transfer (Time t6)

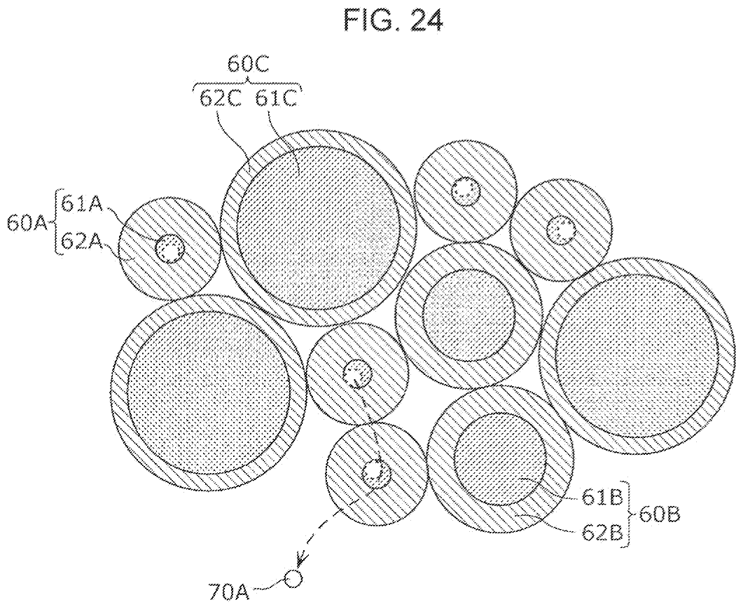

After the second charge resetting is completed, the bias voltage between the counter electrode 12 and the pixel electrode 11 is set to a value larger than or equal to the threshold voltage for the first quantum dot group. More specifically, as illustrated in portion (b) of FIG. 19, the potential V_{ITO} of the counter electrode 12 is set to V2 at the time t6 so that the potential difference between the counter electrode 12 and the pixel electrode 11 becomes the second potential difference. By applying the bias voltage, the holes 70A accumulated in the cores 61A of the quantum dots 60A pass through the shells 62A due to a tunneling effect, are collected by the pixel electrode 11, and are accumulated in the charge accumulation node 41 as illustrated in FIG. 24.

### Step S8: Third Charge Reading (Time t6 to Time t7)

When the second charge transfer is completed, the holes 70A generated in the cores 61A of the quantum dots 60A included in the first quantum dot group have been accumulated in the charge accumulation node 41. The signal detection circuit 14, therefore, measures the amount of charge accumulated in the charge accumulation node 41. The amount of charge accumulated in the charge accumulation node 41 is equal to the amount of signal charge generated in the first quantum dot group. More specifically, as illustrated in portion (c) of FIG. 19, charge is sequentially read from the row <i> through a rolling operation. The rolling operation is the same as in the first charge reading (step 32).

### Step 39: Third Charge Resetting (Time t7 to Time t8)

After the third charge reading is completed, the signal charge accumulated in the charge accumulation node 41 is eliminated. As a result, the photoelectric conversion layers 15 and the charge accumulation nodes 41 are reset, and the pixel array PA is initialized. That is, the state at the time t1 is established again at a time t8. A moving image can be obtained by repeating steps S1 to S9.

When the photoelectric conversion layer 15 includes three or more quantum dot groups having different threshold voltages as described above, signal charge generated in the quantum dot groups can be separately read.

As in the first embodiment, in the driving method illustrated in FIG. 19, an accumulation period does not perfectly match between the quantum dot groups. More specifically, an accumulation period of the third quantum dot group is essentially from the time t1 to an end of a first reading period. An accumulation period of the second quantum dot group is from the time t1 to an end of a second reading period. An accumulation period of the first quantum dot group is from the time t1 to an end of a third reading period. These differences between the accumulation periods are substantially negligible when the reading is performed with a high-speed rolling operation.

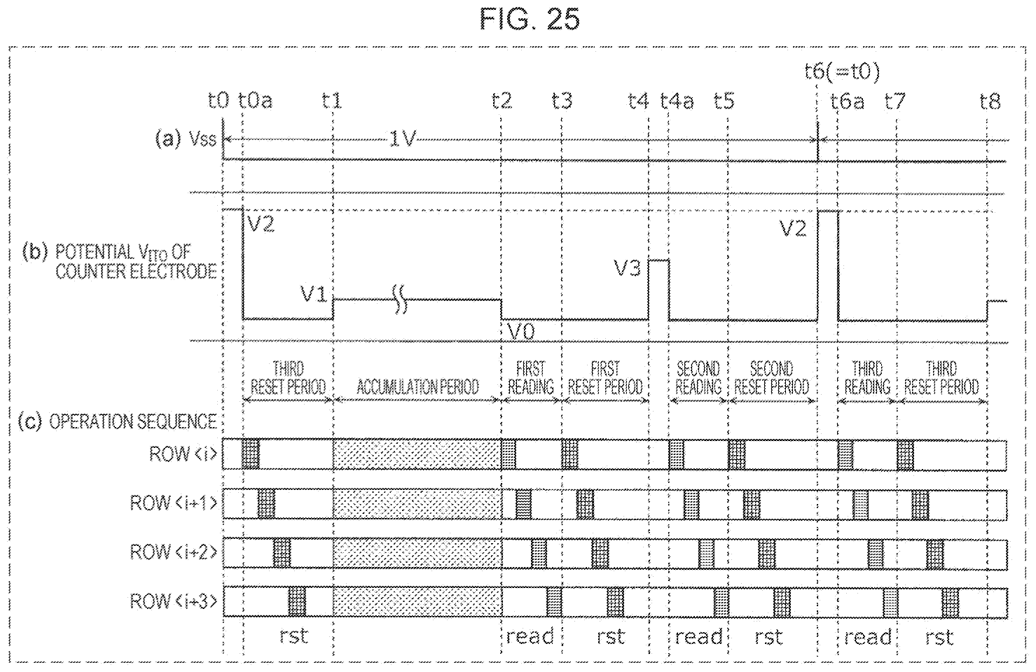

Alternatively, the imaging device may be driven on the basis of an operation illustrated in FIG. 25. FIG. 25 is a timing chart illustrating another example of the method for driving the imaging device according to the present embodiment. In the example illustrated in FIG. 25, after charge is transferred to the charge accumulation node 41 from the quantum dot groups, the sensitivity of the quantum dot groups becomes zero, that is, the quantum dot groups enter the global shutter state. The reading and resetting of the charge transferred to the charge accumulation node 41 from the quantum dot groups are performed in the global shutter state.

From the time t2 to the time t4, for example, the potential V_{ITO} of the counter electrode 12 is set to the potential V0, at which the sensitivity of the quantum dot groups becomes zero. At the potential V0, for example, the potential difference between the counter electrode 12 and the pixel electrode 11 becomes zero. As a result, accumulation of charge during the reading periods and the reset periods due to the rolling operation can be prevented.

In the example illustrated in FIG. 25, the global shutter state is established from the time t0a to the time t1, from the time t2 to the time t4, from the time t4a to the time t6, and from a time t6a to the time t8. A period for transferring signal charge to the charge accumulation node 41 from the quantum dot groups is provided immediately before the time t0a, the time t4a, and the time t6a.

The period from the time t0 to the time t0a, for example, is a period for transferring charge remaining in all the quantum dot groups for the initialization. In the period from the time t0 to the time t0a, the potential V_{ITO} of the counter electrode 12 is V2 as illustrated in portion (b) of FIG. 25. As a result, the holes 70A, 70B, and 70C generated in all the quantum dot groups pass through the shells 62A, 62B, and 62C, respectively, and are transferred to the charge accumulation node 41. That is, the entirety of signal charge in the photoelectric conversion layer 15 is transferred to the charge accumulation node 41.

The period from the time t4 to the time t4a is a period for transferring the holes 70B held in the cores 61B. As illustrated in portion (b) of FIG. 25, the potential V_{ITO} of the counter electrode 12 is V3. As a result, the holes 70B generated in the cores 61B pass through the shells 62B and are transferred to the charge accumulation node 41. That is, signal charge in the second quantum dot group is transferred to the charge accumulation node 41. At this time, the holes 70A generated in the cores 61A of the quantum dots 60A in the first quantum dot groups do not pass through the shells 62A and are held in the cores 61A.

A period from the time t6 to the time t6a is a period for transferring the holes 70A held in the cores 61A. As illustrated in portion (b) of FIG. 25, the potential V_{ITO} of the counter electrode 12 is V2. As a result, the holes 70A generated in the cores 61A pass through the shells 62A and are transferred to the charge accumulation node 41. That is, signal charge in the first quantum dot group is transferred to the charge accumulation node 41.

Signal charge to be read is thus transferred to the charge accumulation node 41 immediately before the global shutter state is established. The reading and the resetting are then performed in the global shutter state. The period from the time t0 to the time t0a, the period from the time t4 to the time t4a, and the period from the time t6 to the time t6a, in which charge is transferred, are shorter than the period for which the global shutter state remains established. An effect caused by the differences between essential lengths of the exposure periods of the quantum dot groups, therefore, can be reduced.

### Fourth Embodiment

Next, a fourth embodiment will be described. The fourth embodiment is different from the first embodiment in that a photoelectric conversion unit includes charge block layers. Differences from the first embodiment will be mainly described hereinafter, and description of common features is omitted or simplified.

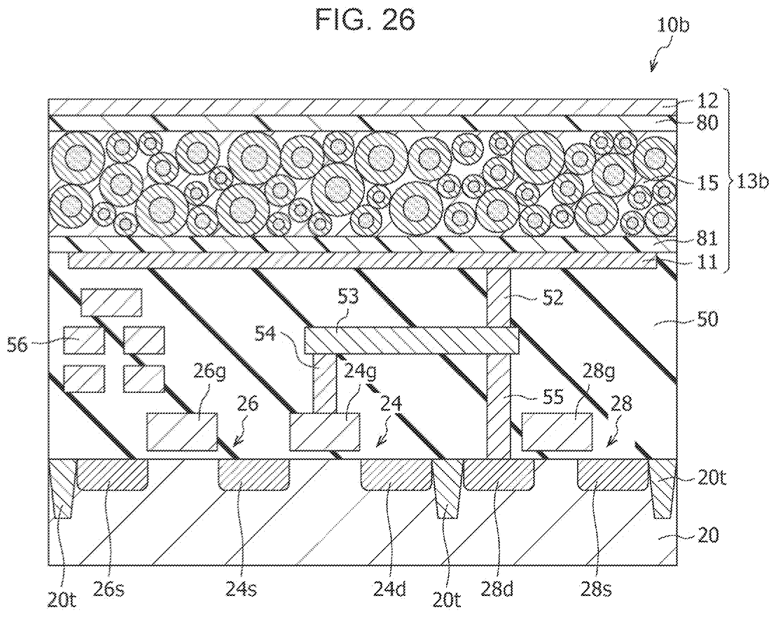

FIG. 26 is a schematic cross-sectional view of the cross-sectional structure of one of pixels of the imaging device according to the present embodiment. As illustrated in FIG. 26, a pixel 10b in the imaging device is different from the pixel 10 according to the first embodiment in that the pixel 10b includes a photoelectric conversion unit 13b instead of the photoelectric conversion unit 13. Unlike the photoelectric conversion unit 13 according to the first embodiment, the photoelectric conversion unit 13b further includes charge block layers 80 and 81.

The charge block layer 80 is located between the counter electrode 12 and the photoelectric conversion layer 15 and is an example of a charge block layer for restricting movement of signal charge to one direction, namely from the photoelectric conversion layer 15 to the pixel electrode 11. When the counter electrode 12 collects electrons, the charge block layer 80 is a so-called “hole block layer”, which restricts movement of holes, not electrons. More specifically, the charge block layer 80 forms a heterojunction barrier against holes and does not form a heterojunction barrier against electrons. Alternatively, the charge block layer 80 may form a heterojunction layer against electrons lower than the heterojunction layer against holes.

When the counter electrode 12 collects holes, the charge block layer 80 is a so-called “electron block layer”, which restricts movement of electrons, not holes. More specifically, the charge block layer 80 forms a heterojunction barrier against electrons and does not form a heterojunction barrier against holes. Alternatively, the charge block layer 80 may form a heterojunction barrier against holes lower than the heterojunction barrier against electrons.

The charge block layer 81 is located between the pixel electrode 11 and the photoelectric conversion layer 15 and is an example of a charge block layer for restricting movement of charge whose polarity is opposite that of signal charge to one direction, namely from the photoelectric conversion layer 15 to the counter electrode 12. When the pixel electrode 11 collects electrons, the charge block layer 81 is a hole block layer. When the pixel electrode 11 collects holes, the charge block layer 81 is an electron block layer.

The charge block layers 80 and 81 are composed, for example, of organic semiconductor materials. The charge block layer 80 is transparent at least to light in a wavelength band absorbed by the photoelectric conversion layer 15. The charge block layers 80 and 81 are composed of materials that function as a hole block layer and an electron block layer.

Examples of the material contained in the charge block layer 80 or 81 that functions as a hole block layer include a fullerene (C60) and a fullerene derivative such as phenyl-C61-butyric acid methyl ester (PCBM). Examples of the material contained in the charge block layer 80 or 81 that functions as an electron block layer include PEDOT: PSS, which is a complex composed of poly(3,4-ethylenedioxythiophene) (PEDOT) and polystyrene sulfonate (PSS), N4,N4′-Di(naphthalen-1-yl)-N4,N4′-bis(4-vinylphenyl)biphenyl-4,4′-diamine (VNPB), poly(3-hexylthiophene-2,5-diyl) (P3HT), and a graphene oxide.

The materials contained in the charge block layers 80 and 81 are not limited to the above examples. For example, the charge block layers 80 and 81 may include an organic semiconductor material or a carbon nanotube.

As described above, with the imaging device according to the present embodiment, injection of charge from an electrode side to a photoelectric conversion layer side during the charge transfer can be suppressed. As a result, a signal-to-noise (S/N) ratio of the imaging device improves. The photoelectric conversion unit 13b may include only either the charge block layer 80 or 81, instead.

In the present embodiment, the photoelectric conversion unit 13b may include, as in the first and second embodiments, two quantum dot groups or, as in the third embodiment, three quantum dot groups.

### Fifth Embodiment

Next, a fifth embodiment will be described. The fifth embodiment is different from the first embodiment in that a photoelectric conversion unit includes a shield electrode. Differences from the first embodiment will be mainly described hereinafter, and description of common features is omitted or simplified.

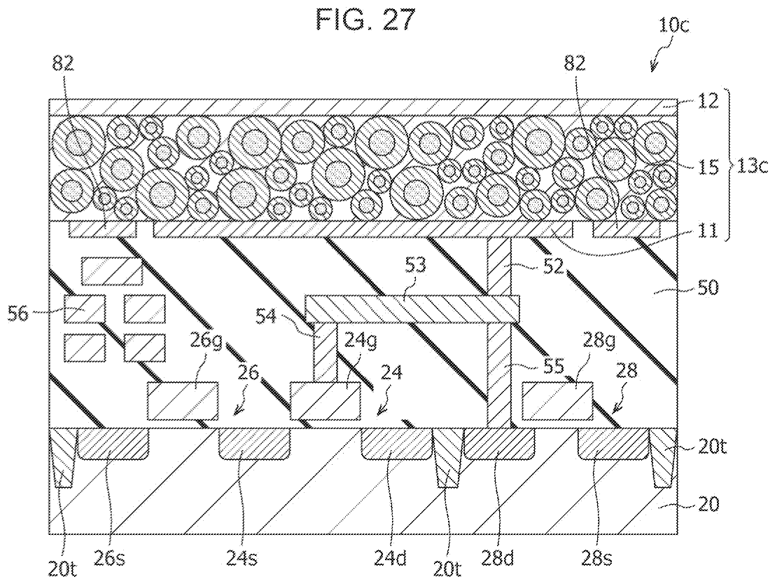

FIG. 27 is a schematic cross-sectional view of the cross-sectional structure of one of pixels of an imaging device according to the present embodiment, As illustrated in FIG. 27, a pixel 10c in the imaging device is different from the pixel 10 according to the first embodiment in that the pixel 10c in the imaging device newly includes a shield electrode 82.

The shield electrode 82 is provided around the pixel electrode 11, and a certain potential is applied to the shield electrode 82. As an appropriate potential is applied to the shield electrode 82, horizontal potential differences are caused in the photoelectric conversion layer 15. As a result, horizontal movement of signal charge in the photoelectric conversion layer 15 can be suppressed.

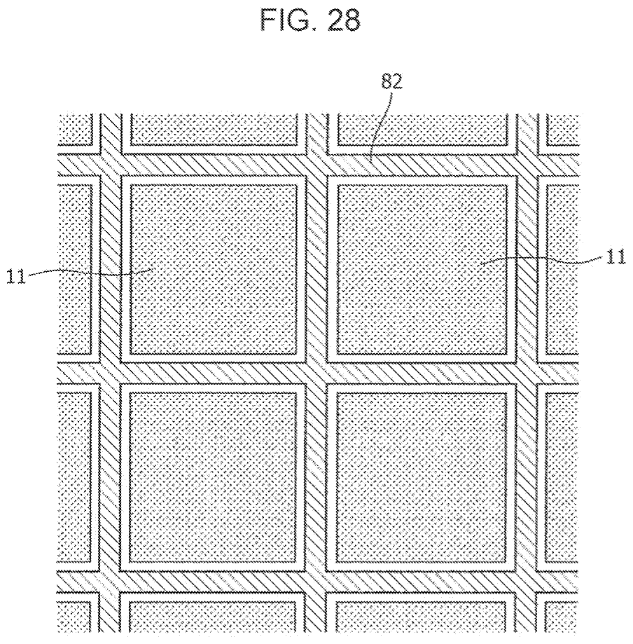

FIG. 28 is a plan view of the planar layout of the pixel electrodes 11 and the shield electrode 82 in the imaging device according to the present embodiment. As illustrated in FIG. 28, a planar shape of the pixel electrodes 11 is square, and the pixel electrodes 11 are arranged in a matrix. In this case, the shield electrode 82 is arranged in a grid pattern between the adjacent pixel electrodes 11 without being in contact with the pixel electrode 11 Shapes of the pixel electrodes 11 and the shield electrode 82 are not particularly limited. For example, the pixel electrode 11 may have a shape of a circle or a regular polygon such as a regular hexagon or a regular octagon, instead, In this case, the shield electrode 82 may be a plate with openings having a shape of a circle or a regular polygon and arranged in a matrix.

As described above, with the imaging device according to the present embodiment, even when the photoelectric conversion layer 15 extends over a plurality of pixels 10c, signal charge generated in the pixels 10c does not mix between the pixels 10c. As a result, mixing between the pixels and deterioration of image quality can be suppressed.

In the present embodiment, the photoelectric conversion unit may include, as in the first and second embodiments, two quantum dot groups or, as in the third embodiment, three quantum dot groups.

### Sixth Embodiment

Next, a sixth embodiment will be described. The sixth embodiment is different from the first embodiment in that a photoelectric conversion unit includes an element isolation region. Differences from the first embodiment will be mainly described hereinafter, and description of common features is omitted or simplified.

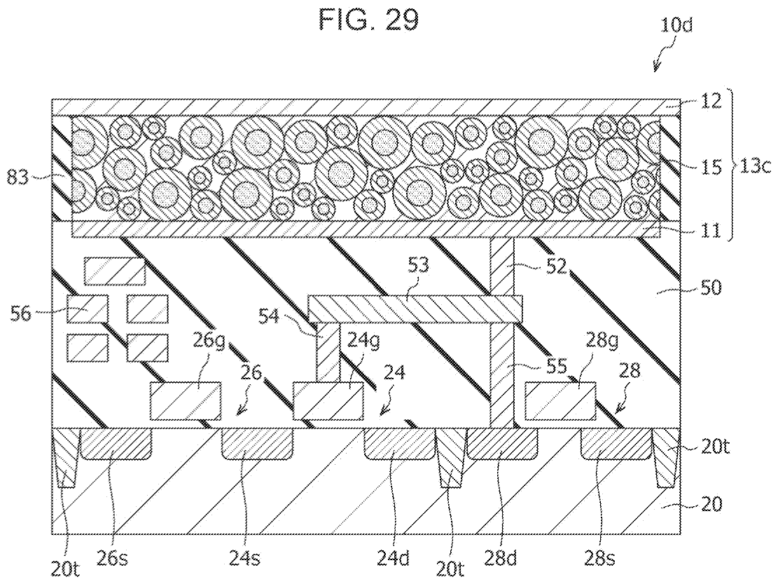

FIG. 29 is a schematic cross-sectional view of the cross-sectional structure of one of pixels of an imaging device according to the present embodiment, As illustrated in FIG. 29, a pixel 10d in the imaging device is different from the pixel 10 according to the first embodiment in that the pixel 10d newly includes a pixel isolation region 83.

The pixel isolation region 83 isolates the photoelectric conversion layer 15 for each of the pixels 10d. The pixel isolation region 83 may also isolate the counter electrode 12.

The pixel isolation region 83 is composed, for example, of a material having electrical insulation. The pixel isolation region 83 may block light or be transparent. As with the shield electrode 82 illustrated in FIG. 28, for example, the pixel isolation region 83 is arranged in a grid pattern in such a way as to surround each of the pixels 10d.

With the above configuration. mixing between the pixels and deterioration of image quality can be sufficiently suppressed.

In the present embodiment, the photoelectric conversion unit may include, as in the first and second embodiments, two quantum dot groups or, as in the third embodiment, three quantum dot groups.

### Seventh Embodiment

Next, a seventh embodiment will be described. The seventh embodiment is different from the first embodiment in that color filters are provided above a photoelectric conversion unit. Differences from the first embodiment will be mainly described hereinafter, and description of common features is omitted or simplified.

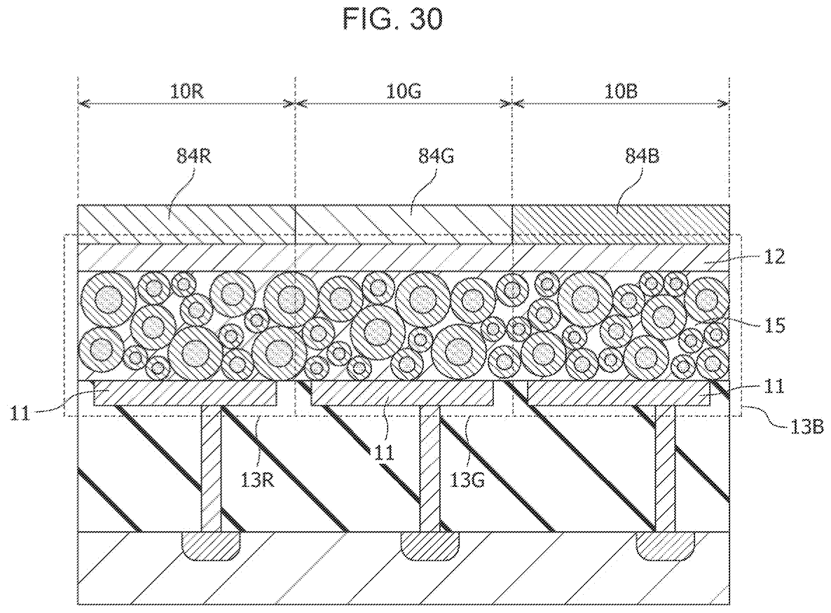

FIG. 30 is a schematic cross-sectional view of the cross-sectional structure of pixels of an imaging device according to the present embodiment. As illustrated in FIG. 30, the imaging device includes pixels 10R, 10G, and 10B. The pixels 10R each include a photoelectric conversion unit 13R and a color filter 84R provided above the photoelectric conversion unit 13R. The pixels 10G each include a photoelectric conversion unit 13G and a color filter 84G provided above the photoelectric conversion unit 13G. The pixels 10B each include a photoelectric conversion unit 138 and a color filter 848 provided above the photoelectric conversion unit 13B.

The photoelectric conversion units 13R, 13G, and 13B have the same structure as the photoelectric conversion unit 13 according to the first embodiment. More specifically, the photoelectric conversion units 13R, 13G, and 13B each include the pixel electrode 11, the counter electrode 12, and the photoelectric conversion layer 15. For example, a first quantum dot group included in the photoelectric conversion layer 15 is sensitive to visible light, and a second quantum dot group is sensitive to infrared light.

The color filter 84R is transparent to red light and blocks light in a visible light band other than red light. The color filter 84G is transparent to green light and blocks light in wavelength bands other than that of green light. The color filter 84B is transparent to blue light and blocks light in wavelength bands other than that of blue light. The color filters 84R, 84G, and 84B are all transparent to infrared light.

With the above configuration, since red light and infrared light are incident on the photoelectric conversion unit 13R of the pixel 10R, signal charge corresponding to red light is generated in the first quantum dot group of the photoelectric conversion unit 13R, and signal charge corresponding to infrared light is generated in the second quantum dot group of the photoelectric conversion unit 13R. Since green light and infrared light are incident on the photoelectric conversion unit 13G of the pixel 10G, signal charge corresponding to green light is generated in the first quantum dot group of the photoelectric conversion unit 13G, and signal charge corresponding to infrared light is generated in the second quantum dot group of the photoelectric conversion unit 13G. Since blue light and infrared light are incident on the photoelectric conversion unit 13B of the pixel 10B, signal charge corresponding to blue light is generated in the first quantum dot group of the photoelectric conversion unit 13B, and signal charge corresponding to infrared light is generated in the second quantum dot group of the photoelectric conversion unit 13B.

As a result, since signal charge corresponding to RGB is generated and read in the pixels 10R, 10G, and 10B, respectively, a color image can be generated. In addition, since signal charge corresponding to infrared light is generated and read in the pixels 10R, 10G, and 10B, an infrared image can be generated.

The number of types of color filter included in the imaging device according to the present embodiment is not limited to three, and may be one, two, or four or more. Wavelengths of light that passes through and is blocked by the color filters are not particularly limited.

In the present embodiment, the photoelectric conversion unit may include, as in the first and second embodiments, two quantum dot groups or, as in the third embodiment, three quantum dot groups.

### Eighth Embodiment

Next, an eighth embodiment will be described.

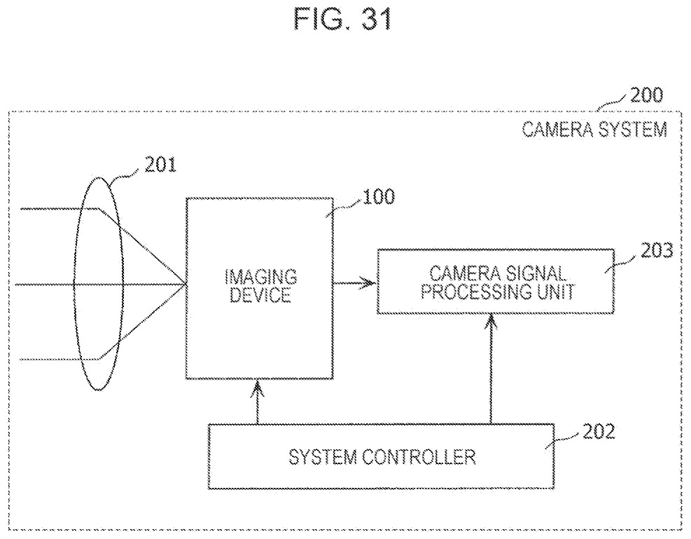

FIG. 31 is a diagram illustrating an example of a camera system 200 including an imaging device according to the present embodiment. Here, a camera system 200 including the imaging device 100 according to the first embodiment will be described. The camera system 200 may include the imaging device according to one of the second to seventh embodiments instead of the imaging device 100.

As illustrated in FIG. 31, the camera system 200 includes a lens optical system 201, the imaging device 100, a system controller 202, and a camera signal processing unit 203.

The lens optical system 201 includes, for example, an autofocus lens, a zoom lens, and a diaphragm. The lens optical system 201 condenses light onto an imaging surface of the imaging device 100. Light that has passed through the lens optical system 201 is incident on the imaging device 100 from a side of the counter electrode 12, and the first and second quantum dot groups included in the photoelectric conversion layer 15 perform photoelectric conversion.

The system controller 202 controls the imaging device 100 and the camera signal processing unit 203. The system controller 202 may be, for example, a microcomputer.

The camera signal processing unit 203 functions as a signal processing circuit that processes signals of data obtained by the imaging device 100 and that outputs the processed signal as an image or data. The camera signal processing unit 203 performs, for example, processing such as gamma correction, color interpolation, spatial interpolation, and white balancing. The camera signal processing unit 203 may be, for example, a digital signal processor (DSP).

### Other Embodiments

Although the imaging device and the method for driving the imaging device according to one or a plurality of aspects have been described on the basis of some embodiments, the present disclosure is not limited to these embodiments. The scope of the present disclosure also includes modes obtained by modifying the above embodiments in various ways conceivable by those skilled in the art and modes obtained by combining components from different embodiments, insofar as the spirit of the present disclosure is not deviated from.

For example, in the above embodiments, spectral sensitivity characteristics of two quantum dot groups may be the same, instead. More specifically, a spectral sensitivity characteristic of first cores of first quantum dots included in a first quantum dot group and a spectral sensitivity characteristic of second cores of second quantum dots included in a second quantum dot group may be the same.

For example, after signal charge generated in the first quantum dot group is transferred to the charge accumulation node 41, the charge accumulation node 41 is reset. Signal charge generated in the second quantum dot group is then transferred to the charge accumulation node 41 and read. As a result, the amount of signal charge transferred to the charge accumulation node 41 at once can be reduced. Because charge accumulated in the charge accumulation node 41 is not saturated, the amount of light that can be detected can be increased. That is, a dynamic range of the sensitivity of the imaging device can be increased.

Alternatively, a quantum dot group to be read may be switched in accordance with the amount of incident light, instead. More specifically, when the amount of incident light is larger than a threshold, only signal charge generated in the first quantum dot group is transferred to the charge accumulation node 41 and read. When the amount of incident light is smaller than the threshold, signal charge generated in the first and second quantum dot groups is transferred to the charge accumulation node 41 and read. With this method, too, saturation of charge accumulated in the charge accumulation node 41 can be suppressed, When signal charge generated in the first and second quantum dot groups is transferred to the charge accumulation node 41, the potential of the counter electrode in the accumulation period may be set to a voltage at which signal charge generated in the first and second quantum dot groups can be transferred to the charge accumulation node 41, instead.

In addition, for example, although an example in which the two quantum dot groups are mingled together in the photoelectric conversion layer 15 has been described, the arrangement of the two quantum dot groups is not limited to this. For example, the first and second quantum dot groups may each form a layer, and the layers may be stacked on each other between the pixel electrode and the counter electrode. That is, the first and second quantum dot groups need not be mingled together, and a first layer formed by the first quantum dot group and a second layer formed by the second quantum dot group may be stacked on each other. For example, a quantum dot group whose threshold voltage is lower is arranged on a side of the pixel electrode, and a quantum dot group whose threshold voltage is higher is arranged on a side of the counter electrode.

In addition, for example, quantum dot groups need not be included in a photoelectric conversion layer in equal proportions. For example, the number of first quantum dots included in the first quantum dot group may be larger or smaller than the number of second quantum dots included in the second quantum dot group.

In addition, the above embodiments may be subjected to various types of modification, replacement, addition, omission, or the like within the scope of the claims or a scope equivalent thereto.

The imaging device and the method for driving the imaging device in the present disclosure can be used, for example, for image sensors included in camera. More specifically, the imaging device and the method for driving the imaging device in the present disclosure can be used for medical cameras, robot cameras, security cameras, vehicle cameras, and the like.

What is claimed is:

1. An imaging device comprising:
a pixel electrode;
a counter electrode that faces the pixel electrode;
a first quantum dot that includes a first core and a first shell and that is located between the pixel electrode and the counter electrode, the first core generating first signal charge, the first shell covering the first core and forming a first heterojunction barrier against the first signal charge;
a second quantum dot that includes a second core and a second shell and that is located between the pixel electrode and the counter electrode, the second core generating second signal charge, the second shell covering the second core and forming a second heterojunction barrier against the second signal charge; and
a charge accumulator that is electrically connected to the pixel electrode and that accumulates the first signal charge and the second signal charge, wherein
the first quantum dot and the second quantum dot are type-II quantum dots,
in a case where a potential difference between the pixel electrode and the counter electrode is a first potential difference, the first signal charge does not pass through the first heterojunction barrier and is held in the first core and the second signal charge passes through the second heterojunction barrier and is collected by the pixel electrode, and
in a case where the potential difference between the pixel electrode and the counter electrode is a second potential difference which is larger than the first potential difference, the first signal charge passes through the first heterojunction barrier and is collected by the pixel electrode.

2. An imaging device comprising:
a pixel electrode;
a counter electrode that faces the pixel electrode;
a first quantum dot that includes a first core and a first shell and that is located between the pixel electrode and the counter electrode, the first core generating first signal charge, the first shell covering the first core;
a second quantum dot that includes a second core and a second shell and that is located between the pixel electrode and the counter electrode, the second core generating second signal charge, the second shell covering the second core; and
a charge accumulator that is electrically connected to the pixel electrode and that accumulates the first signal charge and the second signal charge, wherein
the first quantum dot is one of a hole confining type-II quantum dot and an electron confining type-II quantum dot, and
the second quantum dot is the other of the hole confining type-II quantum dot and the electron confining type-II quantum dot.

3. The imaging device according to claim 2, wherein
in a case where a potential difference between the pixel electrode and the counter electrode is a first potential difference, the first signal charge does not pass through the first shell and is held in the first core and the second signal charge passes through the second shell and is collected by the pixel electrode, and
in a case where the potential difference between the pixel electrode and the counter electrode is a second potential difference which is larger than the first potential difference, the first signal charge passes through the first shell and is collected by the pixel electrode.

4. The imaging device according to claim 1,
wherein the second potential difference is larger than the first potential difference by 0.5 V or more.

5. The imaging device according to claim 1, further comprising:
a voltage supply circuit electrically connected to the counter electrode, wherein
the voltage supply circuit supplies, in a first period, a first voltage to the counter electrode such that the potential difference between the pixel electrode and the counter electrode becomes the first potential difference, and
the voltage supply circuit supplies, in a second period which is different from the first period, a second voltage to the counter electrode such that the potential difference between the pixel electrode and the counter electrode becomes the second potential difference.

6. The imaging device according to claim 1,
wherein, in a case where the potential difference between the pixel electrode and the counter electrode is monotonously increased from the first potential difference to the second potential difference via a threshold potential difference, an amount of signal charge collected by the pixel electrode is saturated at a certain value before the potential difference reaches the threshold potential difference and, after the potential difference exceeds the threshold potential difference, increases from the certain value.

7. The imaging device according to claim 1,
wherein a thickness of the first shell is greater than a thickness of the second shell.

8. The imaging device according to claim 1,
wherein a material of the first shell is different from a material of the second shell.

9. The imaging device according to claim 1,
wherein a spectral sensitivity characteristic of the first core is different from a spectral sensitivity characteristic of the second core.

10. The imaging device according to claim 1,
wherein a spectral sensitivity characteristic of the first core is the same as a spectral sensitivity characteristic of the second core.

11. The imaging device according to claim 3,
wherein the second potential difference is larger than the first potential difference by 0.5 V or more.

12. The imaging device according to claim 1, further comprising:
a voltage supply circuit electrically connected to the counter electrode, wherein
the voltage supply circuit supplies, in a first period, a first voltage to the counter electrode such that the potential difference between the pixel electrode and the counter electrode becomes the first potential difference, and
the voltage supply circuit supplies, in a second period which is different from the first period, a second voltage to the counter electrode such that the potential difference between the pixel electrode and the counter electrode becomes the second potential difference.

13. The imaging device according to claim 3,
wherein, in a case where the potential difference between the pixel electrode and the counter electrode is monotonously increased from the first potential difference to the second potential difference via a threshold potential difference, an amount of signal charge collected by the pixel electrode is saturated at a certain value before the potential difference reaches the threshold potential difference and, after the potential difference exceeds the threshold potential difference, increases from the certain value.

14. The imaging device according to claim 2,
wherein a thickness of the first shell is greater than a thickness of the second shell.

15. The imaging device according to claim 2,
wherein a material of the first shell is different from a material of the second shell.

16. The imaging device according to claim 2,
wherein a spectral sensitivity characteristic of the first core is different from a spectral sensitivity characteristic of the second core.

17. The imaging device according to claim 2,
wherein a spectral sensitivity characteristic of the first core is the same as a spectral sensitivity characteristic of the second core.

18. A method for driving an imaging device including a photoelectric converter that includes a first quantum dot and a second quantum dot between a pixel electrode and a counter electrode, the first quantum dot including a first core and a first shell, the first core generating first signal charge, the first shell covering the first core, the second quantum dot including a second core and a second shell, the second core generating second signal charge, the second shell covering the second core, the method comprising:
(a) setting a potential difference between the pixel electrode and the counter electrode to a first potential difference, to cause the second signal charge generated in the second core to be collected by the pixel electrode while the first signal charge generated in the first core is held in the first core; and
(b) setting the potential difference between the pixel electrode and the counter electrode to a second potential difference which is larger than the first potential difference, to cause the first signal charge in the first core to pass through the first shell and to be collected by the pixel electrode.
